(19) United States
(12) Patent Application Publication
(10) Pub. No.: US 2021/0362240 A1
(43) Pub. Date: Nov. 25, 2021

(54) THREE-DIMENSIONAL PRINTING

(71) Applicant: HEWLETT-PACKARD DEVELOPMENT COMPANY, L.P., Spring, TX (US)

(72) Inventors: Mohammed S. Shaarawi, Corvallis, OR (US); James McKinnell, Corvallis, OR (US); Vladek Kasperchik, Corvallis, OR (US)

(21) Appl. No.: 16/603,332

(22) PCT Filed: Apr. 30, 2018
(86) PCT No.: PCT/US2018/030234

§ 371 Date: Oct. 7, 2019

(51) Int. Cl. B22F 10/43; B22F 10/14; B22F 3/10; B33Y 10/00; B33Y 40/20; B33Y 80/00; B33Y 70/00

(52) U.S. Cl. CPC B22F 10/43; B22F 10/14; B22F 3/1021; B22F 2998/10; B33Y 40/20; B33Y 80/00; B33Y 70/00; B33Y 10/00

(57) ABSTRACT

In an example of a method for three-dimensional (3D) printing, metallic build material layers are patterned to form an intermediate structure. During patterning, a binding agent is selectively applied to define: a build material support structure and a patterned intermediate part. Also during patterning, i) the binding agent and a separate agent including an etch sensitizer or ii) a combined agent including a binder and the etch sensitizer are selectively applied to define a patterned etchable connection between at least a portion of the build material support structure and at least a portion patterned intermediate part. The intermediate structure is heated.

### BACKGROUND

Three-dimensional (3D) printing may be an additive printing process used to make three-dimensional solid parts from a digital model. 3D printing is often used in rapid product prototyping, mold generation, mold master generation, and short run manufacturing. Some 3D printing techniques are considered additive processes because they involve the application of successive layers of material. This is unlike traditional machining processes, which often rely upon the removal of material to create the final part. Some 3D printing methods use chemical binders or adhesives to bind build materials together. Other 3D printing methods involve at least partial curing, thermal merging/fusing, melting, sintering, etc. of the build material. For some materials, at least partial melting may be accomplished using heat-assisted extrusion, and for some other materials (e.g., polymerizable materials), curing or fusing may be accomplished using, for example, ultra-violet light or infrared light.

### BRIEF DESCRIPTION OF THE DRAWINGS

Features of examples of the present disclosure will become apparent by reference to the following detailed description and drawings, in which like reference numerals correspond to similar, though perhaps not identical, components. For the sake of brevity, reference numerals or features having a previously described function may or may not be described in connection with other drawings in which they appear.

FIG. 1 is a flow diagram illustrating an example of a 3D printing method disclosed herein;

FIGS. 2A through 2D are schematic views of different examples of intermediate structures, each of which includes a build material support structure, a patterned intermediate part, and a patterned etchable connection defined between at least a portion of the build material support structure and the patterned intermediate art;

FIGS. 3A through 3J are schematic and partially cross-sectional views depicting the formation of a 3D object and a 3D support structure using an example of the 3D printing method disclosed herein; and

FIG. 4 is a simplified isometric and schematic view of an example of a 3D printing system disclosed herein.

### DETAILED DESCRIPTION

In some examples of three-dimensional (3D) printing, a liquid functional agent is selectively applied to a layer of build material on a build platform to pattern a selected region of the layer, and then another layer of the build material is applied thereon. The liquid functional agent may be applied to this other layer of build material, and these processes may be repeated to form a green part (also known as a green body, and referred to herein as a patterned intermediate part) of the 3D part that is ultimately to be formed. The liquid functional agent is capable of penetrating the layer of build material onto which it is applied, and spreading onto the exterior surface of the build material particles of that layer. The liquid functional agent may include a binder that holds the build material particles of the patterned intermediate part together. The patterned intermediate part may then be exposed to heat to sinter the build material in the patterned intermediate part to form the 3D object/part.

In some 3D printing methods, sections of a patterned intermediate part may not directly be supported by the build platform during the patterning process, and/or may not be supported by a heating mechanism platform during the sintering process. A lack of support can lead to deformation of those sections during patterning and/or sintering. The lack of support is undesirable because it may render the final finished part otherwise unusable, aesthetically unpleasing, etc. In some of the examples disclosed herein, a build material support structure is built as the patterned intermediate part is built, which provides support to the patterned intermediate part during patterning. In any of the examples disclosed herein, the build material support structure is temporarily bound to the patterned intermediate part and thus can be moved to a heating mechanism platform with the patterned intermediate part to provide support during sintering.

As mentioned herein, the build material support structure is temporarily bound to the patterned intermediate part at a patterned etchable connection. In some examples during binder removal and/or sintering, the patterned etchable connection forms an irreversibly etchable connection that includes a sensitized product. In these examples, an etch sensitizer is used to pattern the build material that ultimately forms the irreversibly etchable connection, and during sintering, this etch sensitizer decomposes. The decomposition product reacts with at least one component of the build material, which renders the resulting irreversibly etchable connection more susceptible to etching than the adjacent parts (i.e., the 3D support structure and the 3D object) that are not patterned with the etch sensitizer. The preferential etch property is also self-limiting, because once the volume including the sensitized product (i.e., the irreversibly etchable connection) is at least substantially removed, etching stops. In other examples during binder removal and sintering, the patterned etchable connection forms an irreversibly etchable connection that includes the etch sensitizer. In these examples, the etch sensitizer is used to pattern the build material that ultimately forms the irreversibly etchable connection, and during de-binding and sintering, this etch sensitizer is non-reactive and thus remains in the connection. This remaining etch sensitizer renders the resulting irreversibly etchable connection more susceptible to etching than the adjacent parts (i.e., the 3D support structure and the 3D object) that are not patterned with the etch sensitizer. The preferential etch property is also self-limiting, because once the volume including the etch sensitizer (i.e., the irreversibly etchable connection) is at least substantially removed, etching stops.

### Definitions

Throughout this disclosure, it is to be understood that terms used herein will take on their ordinary meaning in the relevant art unless specified otherwise. Several terms used herein and their meanings are set forth below.

The singular forms “a”, “an”, and “the” include plural referents unless the context clearly dictates otherwise.

The terms comprising, including, containing and various forms of these terms are synonymous with each other and are meant to be equally broad.

As used herein, the terms “remaining region of the patterned intermediate part,” “portion of the patterned intermediate part,” or “layer of the patterned intermediate part” refers to a subsection of the intermediate part that does not have a shape representative of the final 3D printed part, and that includes build material particles patterned with a binding liquid functional agent (i.e., binding agent). In the remaining portion, the portion, or the layer of the patterned intermediate part, the build material particles may or may not be weakly bound together by one or more components of the binding liquid functional agent and/or by attractive force(s) between the build material particles and the binding agent. Moreover, it is to be understood that any build material that is not patterned with the binding agent is not considered to be part of the portion of the patterned intermediate part, even if it is adjacent to or surrounds the portion of the patterned intermediate part.

As used herein, the term “patterned intermediate part” refers to an intermediate part that has a shape representative of the final 3D printed part, and that includes build material particles patterned with the binding agent. In the patterned intermediate part, the build material particles may or may not be weakly bound together by one or more components of the binding agent and/or by attractive force(s) between the build material particles and the binding agent. In some instances, the mechanical strength of the patterned intermediate part is such that it cannot be handled or extracted from a build platform. Moreover, it is to be understood that any build material that is not patterned with the binding liquid functional agent is not considered to be part of the patterned intermediate part, even if it is adjacent to or surrounds the patterned intermediate part.

As used herein, the term “build material support structure” refers to at least one layer of build material that is patterned with the binding agent and that provides support for i) an additional layer of build material that is patterned with the etch sensitizing liquid functional agent, ii) additional layer(s) of build material that are patterned with the binding agent, and/or iii) patterned layers during sintering.

Also as used herein, a “patterned etchable connection” refers to a layer of build material patterned with the etch sensitizing liquid functional agent and positioned between at least a portion of the build material support structure and at least a portion of the patterned intermediate part.

As used herein, the term “intermediate structure” includes the patterned intermediate part and the build material support structure temporarily bound together by the patterned etchable connection.

As used herein, the term “densified intermediate part” refers to a patterned intermediate part from which the liquid components of the binding agent have at least substantially evaporated. At least substantial evaporation of the liquid components of the binding agent leads to densification of the intermediate part, which may be due to capillary compaction. The at least substantial evaporation of the liquid components of the binding agent may also allow the binder to bind the build material particles of the densified intermediate part. In other words, the “densified intermediate part” is an intermediate part with a shape representative of the final 3D printed part and that includes the build material particles bound together by the binder. Compared to the patterned intermediate part, the mechanical strength of the densified intermediate part is greater, and the densified intermediate part can be handled or extracted from the build area platform.

The patterned or densified intermediate part may be known as a green part, but it is to be understood that the term “green” when referring to the patterned intermediate/green part or the densified intermediate/green part does not connote color, but rather indicates that the part is not yet fully processed.

As used herein, the term “at least substantially binder-free intermediate part” refers to an intermediate part that has been exposed to a heating process that initiates thermal decomposition of the binder so that the temporary binder is at least partially removed. In some instances, volatile organic components of, or produced by the thermally decomposed binder are completely removed and a very small amount of non-volatile residue from the thermally decomposed binders may remain. The small amount of the non-volatile residue is generally <2 wt % of the initial binder amount, and in some instances is <0.1 wt % of the initial binder amount. In other instances, the thermally decomposed binder (including any products and residues) is completely removed. In other words, the “at least substantially binder-free intermediate part” refers to an intermediate part with a shape representative of the final 3D printed part and that includes build material particles bound together as a result of i) weak sintering (i.e., low level necking between the particles, which is able to preserve the part shape), or ii) a small amount of the non-volatile binder residue remaining, and/or iii) a combination of i and ii.

The at least substantially binder-free intermediate part may have porosity similar to or greater than the densified intermediate part (due to temporary binder removal), but the porosity is at least substantially eliminated during the transition to the 3D printed part/object.

The at least substantially binder-free intermediate part may be known as a gray part, but it is to be understood that the term “gray” when referring to the at least substantially binder-free gray part does not connote color, but rather indicates that the part is not yet fully processed.

As used herein, the terms “3D printed part or object,” “3D part,” and “3D object” refer to a completed, sintered part.

As used herein, the “etch sensitizing liquid functional agent” refers to a liquid functional agent that includes an etch sensitizer. The etch sensitizing liquid functional agent is used to introduce the etch sensitizer into a defined volume of build material where it is desirable to chemically alter and sensitize the build material. In some examples, the etch sensitizing liquid functional agent is a separate agent used in combination with the binding agent. In these examples, the etch sensitizing liquid functional agent does not include a binder. In other examples, the etch sensitizing liquid functional agent may also include the binder that can temporarily bind the build material of the patterned etchable connection. In these examples, the etch sensitizing liquid functional agent may be referred to as a combined agent, and a separate binding agent may not be used for patterning the etchable connection. Examples of the etch sensitizing liquid functional agent are described further herein below.

As used herein, the “sensitized product” refers to a product of a sensitization reaction between the decomposed etch sensitizer and a component of a build material. In some examples, the sensitized product may be a carbide or nitride.

Also as used herein, the “binding liquid functional agent” or “binding agent” refers to a patterning fluid that includes a binder, but that does not include the etch sensitizer that i) will decompose and react to form the sensitized product upon heating or ii) is non-reactive and will remain in the connection after heating. Examples of the binding agent are described further herein below.

It is to be understood that the weight percentages provided herein may vary, depending upon the weight percentage of the active components within a solution, dispersion, etc. used to form the binding agent, etch sensitizing liquid functional agent, etc., and also on the desired weight percentage of the active components within the binding agent, etch sensitizing liquid functional agent, etc. For example, if a dispersion (to be added to the binding agent) includes 10% of the active component, and the target weight percentage of the active component in the binding agent is 0.01%, then the amount of the dispersion that is added is 0.1% to account for the non-active components in the dispersion.

The examples disclosed herein provide several methods for forming the intermediate structure, and the final sintered object, support, and connection. In some examples, both the etch sensitizing liquid functional agent and the binding liquid functional agent are utilized in forming the patterned etchable connection. In other examples, the patterned etchable connection is formed using the combined agent. In the examples disclosed herein, the same types of build material, etch sensitizing liquid functional agents, and/or binding liquid functional agents may be used. Each of the components will now be described.

Build Material

In examples of the method disclosed herein, the same build material may be used for generating the 3D part, the support structure, and the irreversibly etchable connection. The build material can include metal (metallic) build material.

In an example, the build material particles are a single phase metallic material composed of one element. In this example, the sintering temperature may be below the melting point of the single element.

In another example, the build material particles are composed of two or more elements, which may be in the form of a single phase metallic alloy or a multiple phase metallic alloy. In these other examples, sintering generally occurs over a range of temperatures.

The build material particles may be composed of a single element or alloys. Some examples of the metallic build material particles include steels, stainless steel, bronzes, titanium (Ti) and alloys thereof, aluminum (Al) and alloys thereof, nickel (Ni) and alloys thereof, cobalt (Co) and alloys thereof, iron (Fe) and alloys thereof, nickel cobalt (NiCo) alloys, gold (Au) and alloys thereof, silver (Ag) and alloys thereof, platinum (Pt) and alloys thereof, and copper (Cu) and alloys thereof. Some specific examples include AlSi₁₀Mg, 2xxx series aluminum, 4xxx series aluminum, CoCr MP1, CoCr SP2, MaragingSteel MS1, Hastelloy C, Hastelloy X, NickelAlloy HX, Inconel IN625, Inconel IN718, SS GP1, SS 17-4PH, SS 304, SS 316, SS 316L, SS 420, SS 430, SS 430L, Ti6Al4V, and Ti-6Al-4V ELI7. While several example alloys have been provided, it is to be understood that other alloys may be used.

The temperature(s) at which the metallic particles sinter is/are above the temperature of the environment in which the patterning portion of the 3D printing method is performed (e.g., above 100° C.). In some examples, the metallic build material particles may have a melting point ranging from about 500° C. to about 3500° C. In other examples, the metallic build material particles may be an alloy having a range of melting points.

The build material particles may be similarly sized particles or differently sized particles. The individual particle size of each of the build material particles is up to 100 μm. In an example, the build material particles may be particles, having a particle size ranging from about 1 μm to about 100 μm. In another example, the individual particle size of the build material particles ranges from about 1 μm to about 30 μm. In still another example, the individual particle size of the build material particles ranges from about 2 μm to about 50 μm. In yet another example, the individual particle size of the build material particles ranges from about 5 μm to about 15 μm. In yet another example, the individual particle size of the build material particles ranges from about 3.25 μm to about 5 μm. In yet another example, the individual particle size of the build material particles is about 10 μm. As used herein, the term “individual particle size” refers to the particle size of each individual build material particle. As such, when the build material particles have an individual particle size ranging from about 1 μm to about 100 μm, the particle size of each individual build material particle is within the disclosed range, although individual build material particles may have particle sizes that are different than the particle size of other individual build material particles. In other words, the particle size distribution may be within the given range. The particle size of the build material particles generally refers to the diameter or volume weighted mean/average diameter of the build material particle, which may vary, depending upon the morphology of the particle. The build material particles may also be non-spherical, spherical, random shapes, or combinations thereof.

Etch Sensitizing Liquid Functional Agent

The etch sensitizing liquid functional agent may be used to pattern metallic build material where it is desirable to form the irreversibly etchable connection. Some examples of the etch sensitizing liquid functional agent are used with a separate binding agent; and other examples of the etch sensitizing liquid functional agent are a combined agent that includes the binder, and thus are not used with a separate binding agent.

Whether a separate agent or a combined agent, the etch sensitizing liquid functional agents disclosed herein are aqueous (i.e., water) based liquids including an etch sensitizer.

Examples of the etch sensitizing liquid functional agent include an etch sensitizer that is to i) decompose at a temperature within a de-binding temperature range, a sintering temperature range, or combinations thereof of an intermediate structure to generate a sensitized product within a portion of the intermediate structure that is patterned with the liquid functional agent, the decomposing etch sensitizer being selected from the group consisting of soluble or dispersible ferrocyanides, soluble thiocyanates, a nitrate salt, thermally decomposable soluble organic substances, and a combination thereof, or ii) be non-reactive at the temperature within the de-binding temperature range, the sintering temperature range, or combinations thereof of the intermediate structure to remain within the portion of the intermediate structure that is patterned with the liquid functional agent, the non-reactive etch sensitizer being potassium chloride; any of a surfactant or a dispersing aid; and a balance of water.

In some examples, the etch sensitizer is a compound that is to decompose at a temperature within a de-binding temperature range and/or a sintering temperature range of an intermediate structure to generate a sensitized product within a portion of the intermediate structure that is patterned with the liquid functional agent. The etch sensitizer may be any substance whose thermal decomposition produces a high (e.g., 50%, 60%, 70%, or higher) amount of reactive nitrogen-containing and/or oxygen-containing species that is capable of reacting with one or more components (e.g., chromium) in the build material to degrade the corrosion resistance of the component(s). The decomposed etch sensitizer releases one or more species (i.e., the nitrogen-containing and/or oxygen-containing species) that react with one or more components of the build material, for example, to form a carbide or nitride. As such, in some examples, the etch sensitizer is selected such that it undergoes reaction(s) to initiate sensitized product formation at the high temperatures used in the de-binding and/or sintering stage(s) of the printing process. The sensitized product that is formed is more susceptible to etching than the original build material.

Examples of the decomposing etch sensitizer include soluble or dispersible ferrocyanides, soluble thiocyanates, a nitrate salt, thermally decomposable soluble organic substances producing nitrogen-containing species (such as urea) and a combination thereof. In an example, the soluble ferrocyanide is sodium or potassium hexacyanoferrate, the dispersible ferrocyanide is iron(II,III) hexacyanoferrate(II,III) (Fe₄[Fe(CN)₆]₃ (i.e., Prussian Blue), soluble nitrates are alkali or alkali earth nitrates, such as potassium nitrate, sodium nitrate, magnesium nitrate, calcium nitrate, barium nitrate, ammonium nitrate, and soluble thiocyanates are sodium or potassium thiocyanate. Sodium hexacyanoferrate can precipitate out and then (after the liquid phase of the agent is at least substantially evaporated) decompose to release carbon and nitrogen species that react with chromium in stainless and corrosion resistance steel build materials (patterned with the etch sensitizing liquid functional agent) to form, respectively, chromium carbide and chromium nitride. This example process reduces the chromium content in the patterned volume of build material that would otherwise be available to form an etch protecting chromium oxide during de-binding and/or sintering. As such, the etchable connection that is formed with the etch sensitizing liquid functional agent is more susceptible to etching than the adjacent parts (e.g., 3D object, 3D support structure) that are not formed with the etch sensitizing liquid functional agent.

In other examples, the etch sensitizer is a compound that is non-reactive (i.e., does not decompose, remains intact) at a temperature within the de-binding temperature range and/or the sintering temperature range of an intermediate structure. This non-reactive etch sensitizer remains in the portion of the intermediate structure that is patterned with the liquid functional agent. An example of a non-reactive etch sensitizer includes potassium chloride.

Any examples of the etch sensitizer may be sufficiently soluble in the water portion of the etch sensitizing liquid functional agent. For examples, the solubility of potassium ferrocyanide in water may be at least 289 g/L at 20° C., the solubility of sodium ferrocyanide in water may be 176 g/L at 20° C., the solubility of potassium thiocyanate in water may be 2170 g/L at 20° C., and the solubility of ammonium nitrate in water may be 1500 g/L at 20° C., and thus these etch sensitizers do not have to be suspended in the etch sensitizing liquid functional agent. Some organic etch-sensitizing additives may also have very good solubility in water (e.g., urea—1079 g/L at 20° C.). Non-soluble etch-sensitizing additives, such as iron(II,III) hexacyanoferrate(II,III) can be introduced into etch-sensitizing liquid functional agent formulation in the form of a colloidal dispersion.

The etch sensitizer may be present in the etch sensitizing liquid functional agent in an amount ranging from about 5 wt % to about 75 wt % of the total weight of the etch sensitizing liquid functional agent. In another example, the etch sensitizer may be present in the etch sensitizing liquid functional agent in an amount ranging from about 5 wt % to about 50 wt % of the total weight of the etch sensitizing liquid functional agent. These percentages may include both active etch sensitizer and other non-active components present with the compound.

When the etch sensitizing liquid functional agent is used with a separate binding agent, the etch sensitizing liquid functional agent may include the previously described compound (i.e., etch sensitizer), any of a surfactant or a dispersing aid, and a balance of water. The separate etch sensitizing liquid functional agent may also include humectant(s) and/or co-solvents, antimicrobial agent(s) and/or anti-kogation agent(s), but does not include a binder.

The etch sensitizing liquid functional agent may include surfactant(s) and/or dispersing aid(s). Surfactant(s) and/or dispersing aid(s) may be used to improve the wetting properties and the jettability of the etch sensitizing liquid functional agent. Examples of suitable surfactants and dispersing aids include those that are non-ionic, cationic, or anionic. Examples of suitable surfactants/wetting agents include a self-emulsifiable, non-ionic wetting agent based on acetylenic diol chemistry (e.g., SURFYNOL® SEF from Air Products and Chemicals, Inc.), a non-ionic fluorosurfactant (e.g., CAPSTONE® fluorosurfactants from DuPont, previously known as ZONYL FSO), and combinations thereof. In a specific example, the surfactant is a non-ionic, ethoxylated acetylenic diol (e.g., SURFYNOL® 465 from Air Products and Chemical Inc.). In other examples, the surfactant is an ethoxylated low-foam wetting agent (e.g., SURFYNOL® 440 or SURFYNOL® CT-111 from Air Products and Chemical Inc.) or an ethoxylated wetting agent and molecular defoamer (e.g., SURFYNOL® 420 from Air Products and Chemical Inc.). Still other suitable surfactants include non-ionic wetting agents and molecular defoamers (e.g., SURFYNOL® 104E from Air Products and Chemical Inc.) or secondary alcohol ethoxylates (commercially available as TERGITOL® TMN-6, TERGITOL® 15-S-7, TERGITOL® 15-S-9, etc. from The Dow Chemical Co.). In some examples, it may be desirable to utilize a surfactant having a hydrophilic-lipophilic balance (HLB) less than 10. Examples of suitable dispersing aid(s) include those of the SILQUEST™ series from Momentive, including SILQUEST™ A-1230. Whether a single surfactant or dispersing aid is used or a combination of surfactants and/or dispersing aids is used, the total amount of surfactant(s) and/or dispersing aid(s) in the etch sensitizing liquid functional agent may range from about 0.1 wt % to about 6 wt % based on the total weight of the etch sensitizing liquid functional agent. These percentages may include the active surfactant and/or dispersing aid component and other non-active components present with the active surfactant and/or dispersing aid component.

The etch sensitizing liquid functional agent may also include a humectant and/or co-solvent. Humectants and/or co-solvents may be desirable to increase inkjet decap time, prevent crusting on inkjet nozzles, or to otherwise improve the jettability of the etch sensitizing liquid functional agent. Classes of humectant solvents or co-solvents that may be used in the water-based binder fluid include aliphatic alcohols, aromatic alcohols, diols, glycol ethers, polyglycol ethers, 2-pyrrolidones, caprolactams, formamides, acetamides, glycols, and long chain alcohols. Examples of these co-solvents include primary aliphatic alcohols, secondary aliphatic alcohols, 1,2-alcohols, 1,3-alcohols, 1,5-alcohols, ethylene glycol alkyl ethers, propylene glycol alkyl ethers, higher homologs (C₆-C₁₂) of polyethylene glycol alkyl ethers, N-alkyl caprolactams, unsubstituted caprolactams, both substituted and unsubstituted formamides, both substituted and unsubstituted acetamides, and the like. The humectant and/or co-solvent may be present in an amount ranging from about 0.5 wt % to about 50 wt % (based on the total weight of the etch sensitizing liquid functional agent).

The etch sensitizing liquid functional agent may also include antimicrobial agent(s). Suitable antimicrobial agents include biocides and fungicides. Example antimicrobial agents may include the NUOSEPT® (Ashland Inc.), UCARCIDE™ or KORDEK™ or ROCIMA™ (Dow Chemical Co.), PROXEL® (Arch Chemicals) series, ACTICIDE® B20 and ACTICIDE® M20 and ACTICIDE® MBL (blends of 2-methyl-4-isothiazolin-3-one (MIT), 1,2-benzisothiazolin-3-one (BIT), and Bronopol) (Thor Chemicals), AXIDE™ (Planet Chemical), NIPACIDE™ (Clariant), blends of 5-chloro-2-methyl-4-isothiazolin-3-one (CIT or CMIT) and MIT under the tradename KATHON™ (Dow Chemical Co.), and combinations thereof. In an example, the etch sensitizing liquid functional agent may include a total amount of antimicrobial agents that ranges from about 0.01 wt % to about 1 wt %. In an example, the antimicrobial agent is a biocide and is present in the etch sensitizing liquid functional agent in an amount of about 0.1 wt % (based on the total weight of the etch sensitizing liquid functional agent). These percentages may include both active antimicrobial agent and other non-active components present with the antimicrobial agent.

An anti-kogation agent may also be included in the etch sensitizing liquid functional agent. Kogation refers to the deposit of dried solids on a heating element of a thermal inkjet printhead. Anti-kogation agent(s) is/are included to assist in preventing the buildup of kogation, and thus may be included when the etch sensitizing liquid functional agent is to be dispensed using a thermal inkjet printhead. Examples of suitable anti-kogation agents include oleth-3-phosphate (commercially available as CRODAFOS™ O3 A or CRODAFOS™ N-3 acid) or dextran 500k. Other suitable examples of the anti-kogation agents include CRODAFOS™ HCE (phosphate-ester from Croda Int.), CRODAFOS® N10 (oleth-10-phosphate from Croda Int.), or DISPERSOGEN® LFH (polymeric dispersing agent with aromatic anchoring groups, acid form, anionic, from Clariant), etc. The anti-kogation agent may be present in the etch sensitizing liquid functional agent in an amount ranging from about 0.1 wt % to about 1 wt % of the total weight of the etch sensitizing liquid functional agent.

The balance of the etch sensitizing liquid functional agent is water (e.g., deionized water). As such, the amount of water may vary depending upon the weight percent of the other etch sensitizing liquid functional agent components.

As mentioned herein, other examples of the etch sensitizing liquid functional agent are combined agents that may be used to pattern metallic build material to form the patterned etchable connection without using a separate binding agent. In these other examples, the etch sensitizing liquid functional agent (or combined agent) includes the binder, the etch sensitizer, water, and surfactant(s) and/or dispersing aid(s), and in some instances, may also include antimicrobial agent(s) and/or anti-kogation agent(s). In these examples, any of the previously described etch sensitizers, surfactant(s) and/or dispersing aid(s), antimicrobial agent(s), and/or anti-kogation agent(s) may be used in any of the given amounts.

Examples of suitable binders include latexes (i.e., an aqueous dispersion of polymer particles), polyvinyl alcohol, polyvinylpyrrolidone, and combinations thereof.

Examples of polyvinyl alcohol include low weight average molecular weight polyvinyl alcohols (e.g., from about 13,000 to about 50,000), such as SELVOL™ PVOH 17 from Sekisui. Examples of polyvinylpyrrolidones include low weight average molecular weight polyvinylpyrrolidones (e.g., from about 15,000 to about 19,000), such as LUVITEC™ K 17 from BASF Corp.

The polymer particles of the latex may have several different morphologies. For example, the polymer particles may be individual spherical particles containing polymer compositions of hydrophilic (hard) component(s) and/or hydrophobic (soft) component(s) that may be interdispersed according to IPN (interpenetrating networks), although it is contemplated that the hydrophilic and hydrophobic components may be interdispersed in other ways. For another example, the polymer particles may be made of a hydrophobic core surrounded by a continuous or discontinuous hydrophilic shell. For another example, the polymer particle morphology may resemble a raspberry, in which a hydrophobic core is surrounded by several smaller hydrophilic particles that are attached to the core. The core-shell structure may provide good water dispersibility and jetting reliability when applied via a thermal inkjet printhead. For still another example, the polymer particles may include 2, 3, or 4 particles that are at least partially attached to one another.

The latex polymer particles may have a weight average molecular weight ranging from about 5,000 to about 500,000. As examples, the weight average molecular weight of the latex particles may range from about 100,000 to about 500,000, or from about 150,000 to about 300,000.

Latex particles may include a heteropolymer including a hydrophobic component that makes up from about 65% to about 99.9% (by weight) of the heteropolymer, and a hydrophilic component that makes up from about 0.1% to about 35% (by weight) of the heteropolymer, where the hydrophobic component may have a lower glass transition temperature than the hydrophilic component. In general, a lower content of the hydrophilic component is associated with easier use of the latex particles under typical ambient conditions. As used herein, typical ambient conditions include a temperature range from about 20° C. to about 25° C., an atmospheric pressure of about 100 kPa (kilopascals), and a relative humidity ranging from about 30% to about 90%. The glass transition temperature of the latex particles may range from about −20° C. to about 130° C., or in a specific example, from about 60° C. to about 105° C.

Examples of monomers that may be used to form the hydrophobic component include C₄ to C₈ alkyl acrylates or methacrylates, styrene, substituted methyl styrenes, polyol acrylates or methacrylates, vinyl monomers, vinyl esters, ethylene, maleate esters, fumarate esters, itaconate esters, or the like. Some specific examples include methyl methacrylate, butyl acrylate, butyl methacrylate, hexyl acrylate, hexyl methacrylate, ethyl acrylate, ethyl methacrylate, propyl acrylate, propyl methacrylate, 2-ethylhexyl acrylate, 2-ethylhexyl methacrylate, hydroxyethyl acrylate, lauryl acrylate, lauryl methacrylate, octadecyl acrylate, octadecyl methacrylate, isobornyl acrylate, isobornyl methacrylate, stearyl methacrylate, ethylene glycol dimethacrylate, diethylene glycol dimethacrylate, triethylene glycol dimethacrylate, tetrahydrofurfuryl acrylate, alkoxylated tetrahydrofurfuryl acrylate, 2-phenoxyethyl methacrylate, benzyl acrylate, ethoxylated nonyl phenol methacrylate, cyclohexyl methacrylate, trimethyl cyclohexyl methacrylate, t-butyl methacrylate, n-octyl methacrylate, tridecyl methacrylate, isodecyl acrylate, dimethyl maleate, dioctyl maleate, acetoacetoxyethyl methacrylate, diacetone acrylamide, pentaerythritol tri-acrylate, pentaerythritol tetra-acrylate, pentaerythritol tri-methacrylate, pentaerythritol tetra-methacrylate, divinylbenzene, styrene, methylstyrenes (e.g., α-methyl styrene, p-methyl styrene), 1,3-butadiene, vinyl chloride, vinylidene chloride, vinylbenzyl chloride, acrylonitrile, methacrylonitrile, N-vinyl imidazole, N-vinylcarbazole, N-vinyl-caprolactam, combinations thereof, derivatives thereof, or mixtures thereof.

The heteropolymer may be formed of at least two of the previously listed monomers, or at least one of the previously listed monomers and a higher T_{g} hydrophilic monomer, such as an acidic monomer. Examples of acidic monomers that can be polymerized in forming the latex polymer particles include acrylic acid, methacrylic acid, ethacrylic acid, dimethylacrylic acid, maleic anhydride, maleic acid, vinylsulfonate, cyanoacrylic acid, vinylacetic acid, allylacetic acid, ethylidineacetic acid, propylidineacetic acid, crotonoic acid, fumaric acid, itaconic acid, sorbic acid, angelic acid, cinnamic acid, styrylacrylic acid, citraconic acid, glutaconic acid, aconitic acid, phenylacrylic acid, acryloxypropionic acid, aconitic acid, phenylacrylic acid, acryloxypropionic acid, vinylbenzoic acid, N-vinylsuccinamidic acid, mesaconic acid, methacroylalanine, acryloylhydroxyglycine, sulfoethyl methacrylic acid, sulfopropyl acrylic acid, styrene sulfonic acid, sulfoethylacrylic acid, 2-methacryloyloxymethane-1-sulfonic acid, 3-methacryoyloxypropane-1-sulfonic acid, 3-(vinyloxy)propane-1-sulfonic acid, ethylenesulfonic acid, vinyl sulfuric acid, 4-vinylphenyl sulfuric acid, ethylene phosphonic acid, vinyl phosphoric acid, vinyl benzoic acid, 2 acrylamido-2-methyl-1-propanesulfonic acid, combinations thereof, derivatives thereof, or mixtures thereof. Other examples of high T_{g} hydrophilic monomers include acrylamide, methacrylamide, monohydroxylated monomers, monoethoxylated monomers, polyhydroxylated monomers, or polyethoxylated monomers.

In examples, the aqueous dispersion of polymer particles (latexes) may be produced by emulsion polymerization or co-polymerization of any of the previously listed monomers. Other suitable techniques, specifically for generating a core-shell structure, may be used, such as: i) grafting a hydrophilic shell onto the surface of a hydrophobic core, ii) copolymerizing hydrophobic and hydrophilic monomers using ratios that lead to a more hydrophilic shell, iii) adding hydrophilic monomer (or excess hydrophilic monomer) toward the end of the copolymerization process so there is a higher concentration of hydrophilic monomer copolymerized at or near the surface, or iv) any other method known in the art to generate a more hydrophilic shell relative to the core.

In some other examples, the latex particles may have a structure which is not necessarily limited to a core-shell structure, i.e., apart from a core-shell structure, latex particles may also or alternatively have a single phase morphology, may be partially occluded, may be multiple-lobed, or may have combinations of these structural features.

In an example, the polymer particles may be made of two different copolymer compositions. These compositions may be fully separated “core-shell” polymers, partially occluded mixtures, or intimately comingled as a “polymer solution.” In another example, the polymer particle morphology may resemble a raspberry, as stated above, in which a hydrophobic core is surrounded by a large number of smaller hydrophilic particles that are attached to the core. In still another example, the polymer particles may include 2, 3, 4, or more relatively large particle “lobes” surrounding a smaller polymer core.

The polymer particles may be any latex polymer (i.e., polymer that is capable of being dispersed in an aqueous medium) that is jettable via inkjet printing (e.g., thermal inkjet printing or piezoelectric inkjet printing). In some examples disclosed herein, the polymer particles are heteropolymers or co-polymers. The heteropolymers may include a more hydrophobic component and a more hydrophilic component. In these examples, the hydrophilic component renders the particles dispersible in the binder agent, while the hydrophobic component is capable of coalescing upon exposure to heat in order to temporarily bind the metal powder build material particles together.

Examples of low T_{g} monomers that may be used to form the hydrophobic component include C₄ to C₈ alkyl acrylates or methacrylates, styrene, substituted methyl styrenes, polyol acrylates or methacrylates, vinyl monomers, vinyl esters, or the like. Some specific examples include methyl methacrylate, butyl acrylate, butyl methacrylate, hexyl acrylate, hexyl methacrylate, ethyl acrylate, ethyl methacrylate, propyl acrylate, propyl methacrylate, 2-ethylhexyl acrylate, 2-ethylhexy methacrylate, hydroxyethyl acrylate, lauryl acrylate, lauryl methacrylate, octadecyl acrylate, octadecyl methacrylate, isobornyl acrylate, isobornyl methacrylate, stearyl methacrylate, ethylene glycol dimethacrylate, diethylene glycol dimethacrylate, triethylene glycol dimethacrylate, tetrahydrofurfuryl acrylate, alkoxylated tetrahydrofurfuryl acrylate, 2-phenoxyethyl methacrylate, benzyl acrylate, ethoxylated nonyl phenol methacrylate, cyclohexyl methacrylate, trimethyl cyclohexyl methacrylate, t-butyl methacrylate, n-octyl methacrylate, trydecyl methacrylate, isodecyl acrylate, dimethyl maleate, dioctyl maleate, acetoacetoxyethyl methacrylate, diacetone acrylamide, pentaerythritol tri-acrylate, pentaerythritol tetra-acrylate, pentaerythritol tri-methacrylate, pentaerythritol tetra-methacrylate, divinylbenzene, styrene, methylstyrenes (e.g., α-methyl styrene, p-methyl styrene), vinyl chloride, vinylidene chloride, vinylbenzyl chloride, acrylonitrile, methacrylonitrile, N-vinyl imidazole, N-vinylcarbazole, N-vinyl-caprolactam, combinations thereof, derivatives thereof, or mixtures thereof.

Examples of monomers that can be used in forming the polymer particles include acrylic acid, methacrylic acid, ethacrylic acid, dimethylacrylic acid, maleic anhydride, maleic acid, vinylsulfonate, cyanoacrylic acid, vinylacetic acid, allylacetic acid, ethylidineacetic acid, propylidineacetic acid, crotonoic acid, fumaric acid, itaconic acid, sorbic acid, angelic acid, cinnamic acid, styrylacrylic acid, citraconic acid, glutaconic acid, aconitic acid, phenylacrylic acid, acryloxypropionic acid, aconitic acid, phenylacrylic acid, acryloxypropionic acid, vinylbenzoic acid, N-vinylsuccinamidic acid, mesaconic acid, methacroylalanine, acryloylhydroxyglycine, sulfoethyl methacrylic acid, sulfopropyl acrylic acid, styrene sulfonic acid, sulfoethylacrylic acid, 2-methacryloyloxymethane-1-sulfonic acid, 3-methacryoyloxypropane-1-sulfonic acid, 3-(vinyloxy)propane-1-sulfonic acid, ethylenesulfonic acid, vinyl sulfuric acid, 4-vinylphenyl sulfuric acid, ethylene phosphonic acid, vinyl phosphoric acid, vinyl benzoic acid, 2 acrylamido-2-methyl-1-propanesulfonic acid, combinations thereof, derivatives thereof, or mixtures thereof. Other examples of high T_{g} hydrophilic monomers include acrylamide, methacrylamide, monohydroxylated monomers, monoethoxylated monomers, polyhydroxylated monomers, or polyethoxylated monomers.

In an example, the selected monomer(s) is/are polymerized to form a polymer, heteropolymer, or copolymer. In some examples, the monomer(s) are polymerized with a co-polymerizable surfactant. In some examples, the co-polymerizable surfactant can be a polyoxyethylene compound. In some examples, the co-polymerizable surfactant can be a Hitenol® compound e.g., polyoxyethylene alkylphenyl ether ammonium sulfate, sodium polyoxyethylene alkylether sulfuric ester, polyoxyethylene styrenated phenyl ether ammonium sulfate, or mixtures thereof. Any suitable polymerization process may be used. The polymer particles may have a particle size that can be jetted via thermal inkjet printing or piezoelectric printing or continuous inkjet printing. In an example, the particle size of the polymer particles ranges from about 10 nm to about 300 nm.

In some examples, the polymer particles have a Minimum Film-Forming Temperature (MFFT) or a glass transition temperature (T_{g}) that is greater (e.g., >) than ambient temperature. In other examples, the polymer particles have an MFFT or glass transition temperature (T_{g}) that is much greater (e.g., >>) than ambient temperature (i.e., at least 15° higher than ambient). As used therein, “ambient temperature” may refer to room temperature (e.g., ranging about 18° C. to about 22° C.), or to the temperature of the environment in which the 3D printing method is performed. Examples of the 3D printing environment ambient temperature may range from about 40° C. to about 50° C. The MFFT or the glass transition temperature T_{g} of the bulk material (e.g., the more hydrophobic portion) of the polymer particles may range from 25° C. to about 125° C. In an example, the MFFT or the glass transition temperature T_{g} of the bulk material (e.g., the more hydrophobic portion) of the polymer particles is about 40° C. or higher. The MFFT or the glass transition temperature T_{g} of the bulk material may be any temperature that enables the polymer particles to be inkjet printed without becoming too soft at the printer operating temperatures.

In an example, the polymer particles may have a MFFT or glass transition temperature ranging from about 125° C. to about 200° C. In an example, the polymer particles may have a MFFT or glass transition temperature of about 160° C.

The weight average molecular weight of the polymer particles may range from about 10,000 Mw to about 500,000 Mw. In some examples, the weight average molecular weight of the polymer particles ranges from about 100,000 Mw to about 500,000 Mw. In some other examples, the weight average molecular weight of the polymer particles ranges from about 150,000 Mw to 300,000 Mw.

When each of the polymer particles contains a low T_{g} hydrophobic component and a high T_{g} hydrophilic component, the polymer particles may be prepared by any suitable method. As examples, the polymer particles may be prepared by one of the following methods.

In an example, the polymer particles may be prepared by polymerizing high T_{g} hydrophilic monomers to form the high T_{g} hydrophilic component and attaching the high T_{g} hydrophilic component onto the surface of the low T_{g} hydrophobic component.

In another example, each of the polymer particles may be prepared by polymerizing the low T_{g} hydrophobic monomers and the high T_{g} hydrophilic monomers at a ratio of the low T_{g} hydrophobic monomers to the high T_{g} hydrophilic monomers that ranges from 5:95 to 30:70. In this example, the soft low T_{g} hydrophobic monomers may dissolve in the hard high T_{g} hydrophilic monomers.

In still another example, each of the polymer particles may be prepared by starting the polymerization process with the low T_{g} hydrophobic monomers, then adding the high T_{g} hydrophilic monomers, and then finishing the polymerization process. In this example, the polymerization process may cause a higher concentration of the high T_{g} hydrophilic monomers to polymerize at or near the surface of the low T_{g} hydrophobic component.

In still another example, each of the polymer particles may be prepared by starting a copolymerization process with the low T_{g} hydrophobic monomers and the high T_{g} hydrophilic monomers, then adding additional high T_{g} hydrophilic monomers, and then finishing the copolymerization process. In this example, the copolymerization process may cause a higher concentration of the high T_{g} hydrophilic monomers to copolymerize at or near the surface of the low T_{g} hydrophobic component.

The low T_{g} hydrophobic monomers and/or the high T_{g} hydrophilic monomers used in any of these examples may be any of the low T_{g} hydrophobic monomers and/or the high T_{g} hydrophilic monomers (respectively) listed above. In an example, the low T_{g} hydrophobic monomers are selected from the group consisting of C₄ to C₈ alkyl acrylate monomers, C₄ to C₈ alkyl methacrylate monomers, styrene monomers, substituted methyl styrene monomers, vinyl monomers, vinyl ester monomers, and combinations thereof; and the high T_{g} hydrophilic monomers are selected from the group consisting of acidic monomers, unsubstituted amide monomers, alcoholic acrylate monomers, alcoholic methacrylate monomers, C₁ to C₂ alkyl acrylate monomers, C₁ to C₂ alkyl methacrylate monomers, and combinations thereof.

The resulting polymer particles may exhibit a core-shell structure, a mixed or intermingled polymeric structure, or some other morphology.

In an example, the binder is present in the combined agent in an amount ranging from about 1 wt % to about 30 wt % based on a total weight of the combined agent. In another example, the binder is present in the combined agent in an amount ranging from about 2 wt % to about 20 wt % based on the total weight of combined agent. These percentages may include both active binder and other non-active components present with the binder.

Example formulations of the etch sensitizer liquid functional agent that does include a binder, and thus may be used without a separate binding agent, are shown in Tables 1 and 2.

TABLE 1

| Component | | Actives | Target | Formulation |
|---|---|---|---|---|
| Type | Specific Components | (wt %) | (wt %) | (wt %) |
| Binder | Polyvinyl alcohol | 100.00 | 13.61 | 13.61 |
| | Polyvinyl pyrrolidone | 100.00 | 3.26 | 3.26 |
| Surfactant/ | Tergitol ® 15-S-7 | 90.00 | 1.47 | 1.63 |
| Dispersing aid | | | | |
| Antimicrobial | Acticide ® M20 | 10.00 | 0.01 | 0.10 |
| | (stock solution) | | | |
| Etch | Potassium | 100.00 | 16.67 | 16.67 |
| Sensitizer | ferrocyanide | | | |
| Water | Deionized Water | — | 64.98 | 64.73 |

TABLE 2

| Component | | Actives | Target | Formulation |
|---|---|---|---|---|
| Type | Specific Components | (wt %) | (wt %) | (wt %) |
| Binder | Polyvinyl alcohol | 100.00 | 13.61 | 13.61 |
| | Polyvinyl pyrrolidone | 100.00 | 3.26 | 3.26 |
| Surfactant/ | Tergitol ® 15-S-7 | 90.00 | 1.47 | 1.63 |
| Dispersing aid | | | | |
| Antimicrobial | Acticide ® M20 | 10.00 | 0.01 | 0.10 |
| | (stock solution) | | | |
| Etch | Potassium | 100.00 | 16.67 | 16.67 |
| Sensitizer | Thiocyanate | | | |
| Water | Deionized Water | — | 64.98 | 64.73 |

Binding Liquid Functional Agent

The binding liquid functional agent (i.e., binding agent) may be used to pattern metallic build material where it is desirable to form the 3D object and where it is desirable to form the 3D support structure. The binding agent may also be used in combination with examples of the etch sensitizing liquid functional agent that do not include a binder to pattern build material where it is desirable to form the irreversibly etchable connection.

The binding agent includes the binder. Any of the binders set forth herein for examples of the combined agent may be used in the binding agent. In an example, the binder is present in the binding agent in an amount ranging from about 1 wt % to about 30 wt % based on a total weight of the binding agent. In another example, the binder is present in the binding agent in an amount ranging from about 2 wt % to about 20 wt % based on the total weight of binding agent. These percentages may include both active binder and other non-active components present with the binder.

In addition to the binder, the binding agent may also include water, co-solvent(s), surfactant(s) and/or dispersing aid(s), antimicrobial agent(s), and/or anti-kogation agent(s). In these examples, any of the previously described surfactant(s) and/or dispersing aid(s), antimicrobial agent(s), and/or anti-kogation agent(s) may be used in any of the given amounts, except that the weight percentages are with respect to a total weight of the binding agent.

The co-solvent may be an organic co-solvent present in the binding agent in an amount up to about 50 wt % (based on the total weight of the binding agent). It is to be understood that other amounts outside of this range may also be used depending, at least in part, on the jetting architecture used to dispense the binding agent. The organic co-solvent may be any water miscible, high-boiling point solvent, which has a boiling point of at least 120° C. Classes of organic co-solvents that may be used include aliphatic alcohols, aromatic alcohols, diols, glycol ethers, polyglycol ethers, 2-pyrrolidones/pyrrolidinones, caprolactams, formamides, acetamides, glycols, and long chain alcohols. Examples of these co-solvents include primary aliphatic alcohols, secondary aliphatic alcohols, 1,2-alcohols, 1,3-alcohols, 1,5-alcohols, ethylene glycol alkyl ethers, propylene glycol alkyl ethers, higher homologs (C₆-C₁₂) of polyethylene glycol alkyl ethers, N-alkyl caprolactams, unsubstituted caprolactams, both substituted and unsubstituted formamides, both substituted and unsubstituted acetamides, and the like. In some examples, the binding agent may include 2-pyrrolidone, 2-methyl-1,3-propanediol, 1-(2-hydroxyethyl)-2-pyrrolidone, 1,2-butanediol, or combinations thereof.

The composition of the binding liquid functional agent may be similar to examples of the etch sensitizing liquid functional agent except that the etch sensitizer is excluded from the formulation of the binding liquid functional agent.

An example formulation of the binding liquid functional agent is shown in Table 3.

TABLE 3

| Component | | | | |
|---|---|---|---|---|
| Type | Components | Actives | Target | Formulation |
| Binder | Polyvinyl alcohol | 100.00 | 13.61 | 13.61 |
| | Polyvinyl pyrrolidone | 100.00 | 3.26 | 3.26 |
| Surfactant/ | Tergitol ® 15-S-7 | 90.00 | 1.47 | 1.63 |
| Dispersing aid | | | | |
| Antimicrobial | Acticide ® M20 | 10.00 | 0.01 | 0.1 |
| | (stock solution) | | | |
| Water | Deionized Water | — | 81.65 | 81.40 |

Methods

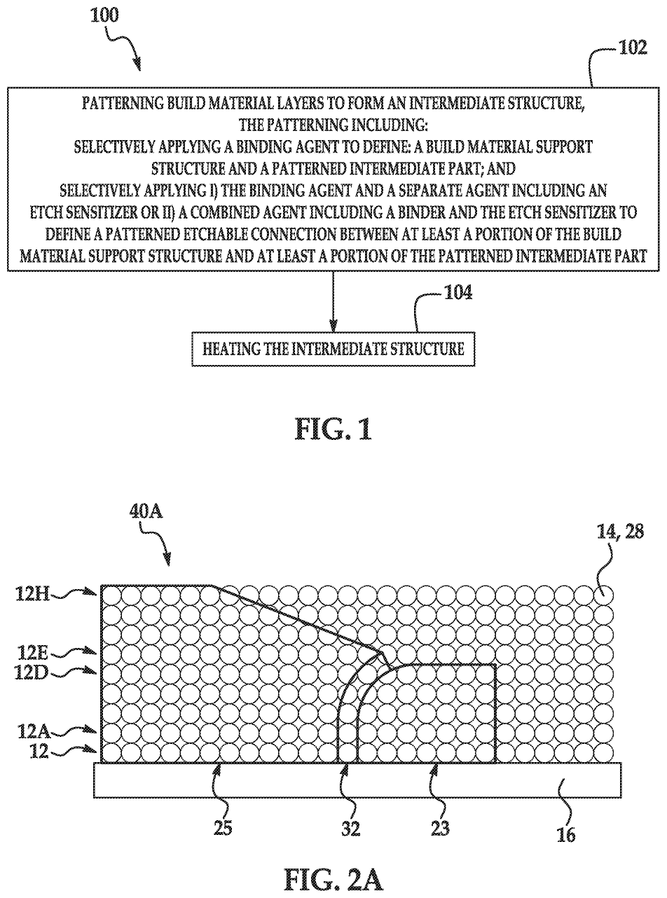

An example of the 3D printing method 100, in which an etch sensitizing liquid functional agent and a binding agent are used, is depicted in FIG. 1. Generally, the method 100 includes patterning metallic build material layers to form an intermediate structure, the patterning including: selectively applying a binding agent to define: a build material support structure and a patterned intermediate part; and selectively applying i) the binding agent and a separate agent including an etch sensitizer or ii) a combined agent including a binder and the etch sensitizer to define a patterned etchable connection between at least a portion of the build material support structure and at least a portion of the patterned intermediate part (reference numeral 102); and heating the intermediate structure (reference numeral 104).

Any examples of the build material, the binding agent, and the etch sensitizing liquid functional agent described herein may be used in the method 100. Furthermore, the method 100 may be used to form 3D objects, 3D support structures, and irreversibly etchable connections of any size and/or shape, as long as the irreversibly etchable connection is located between at least a portion of the 3D object and the 3D support structure, and provides a preferentially etchable junction between the 3D object and the 3D support structure.

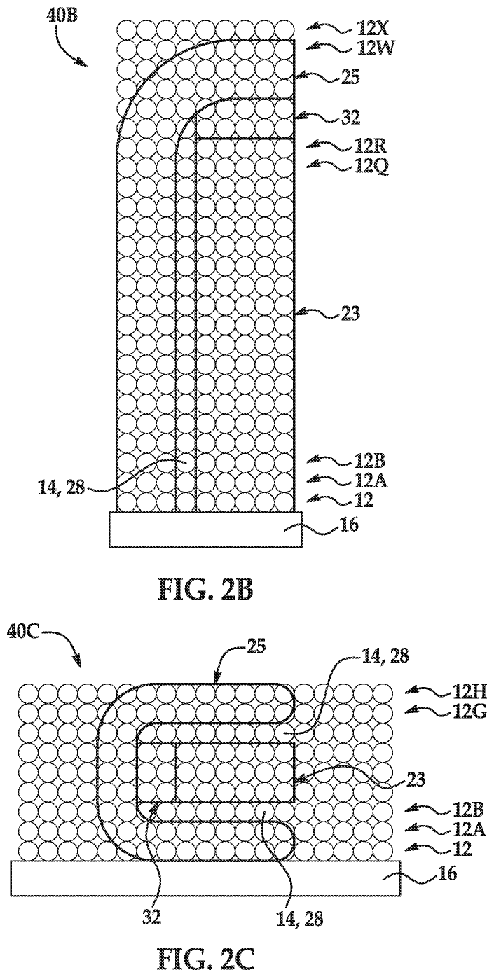

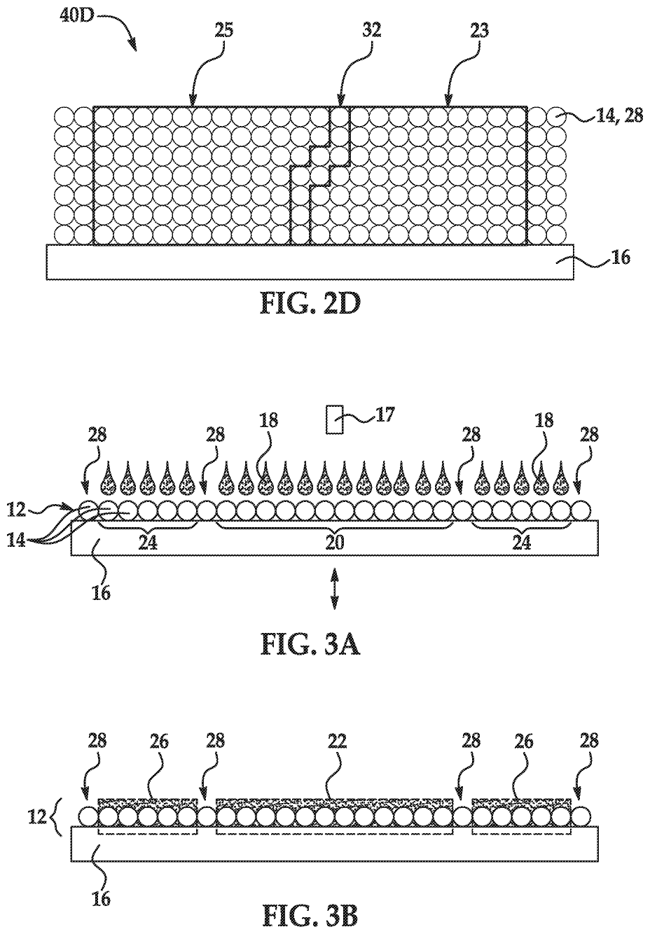

At reference numeral 102 in FIG. 1, metallic build material layers are patterned to form the intermediate structure, which is ultimately heated to form the 3D object, 3D support structure, and irreversibly etchable connection. FIGS. 2A through 2D depict various examples of the intermediate structures 40A, 40B, 40C, 40D that may be made using the method 100.

In an example, patterning the metallic build material layers includes: iteratively applying individual metallic build material layers 12, 12A, 12B, etc.; selectively applying the binding agent to at least some, or to each, of the individual metallic build material layers to define several layers of the build material support structure 23 and several layers of the patterned intermediate part 25; and selectively applying i) the binding agent and the separate agent or ii) the combined agent on each of the individual metallic build material layers to define the patterned etchable connection between the several layers of the build material support structure 23 and the several layers of the patterned intermediate part 25. In some examples (e.g., FIGS. 2A and 2D), the patterned etchable connection 23 alone separates the build material support structure 23 from the patterned intermediate part 25, and in other examples (e.g., FIGS. 2B and 2C), one or more layers of non-patterned build material 28 and the patterned etchable connection 23 separate the build material support structure 23 from the patterned intermediate part 25.

In the examples shown in FIGS. 2A through 2D, several build material layers 12, 12A, 12B . . . 12H (FIG. 2A), etc. have been applied and patterned to define different examples of the build material support structure 23, the patterned intermediate part 25, and the patterned etchable connection 32. Repeated application and patterning may be performed until the total number of build material layers that are patterned form a complete build material support structure 23 according to a 3D model of the 3D support structure, a complete patterned intermediate part 25 according to a 3D model of the 3D object, and a complete patterned etchable connection 32 according to a 3D model of the irreversibly etchable connection.

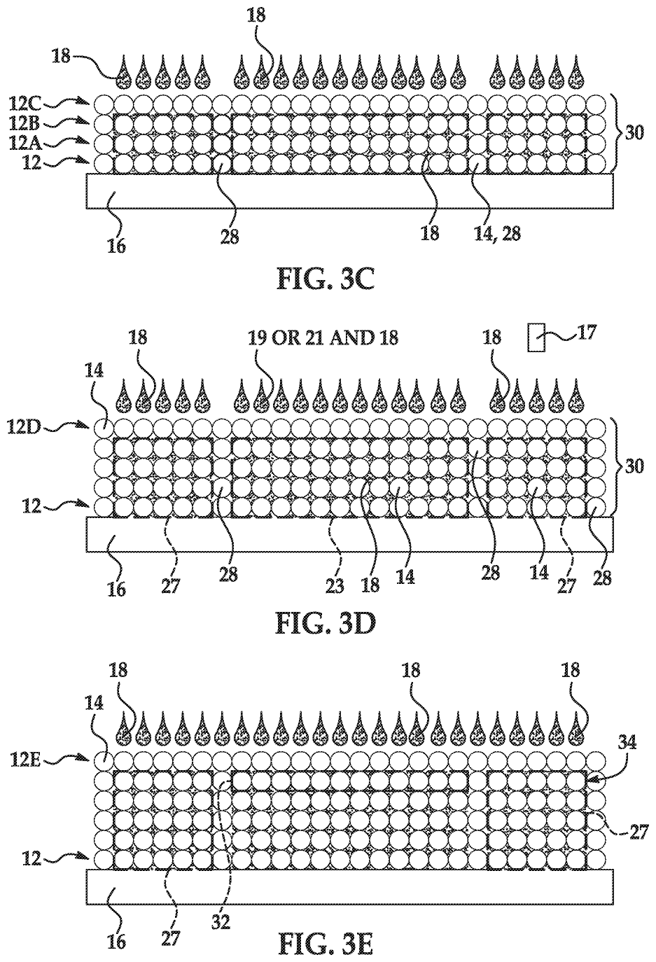

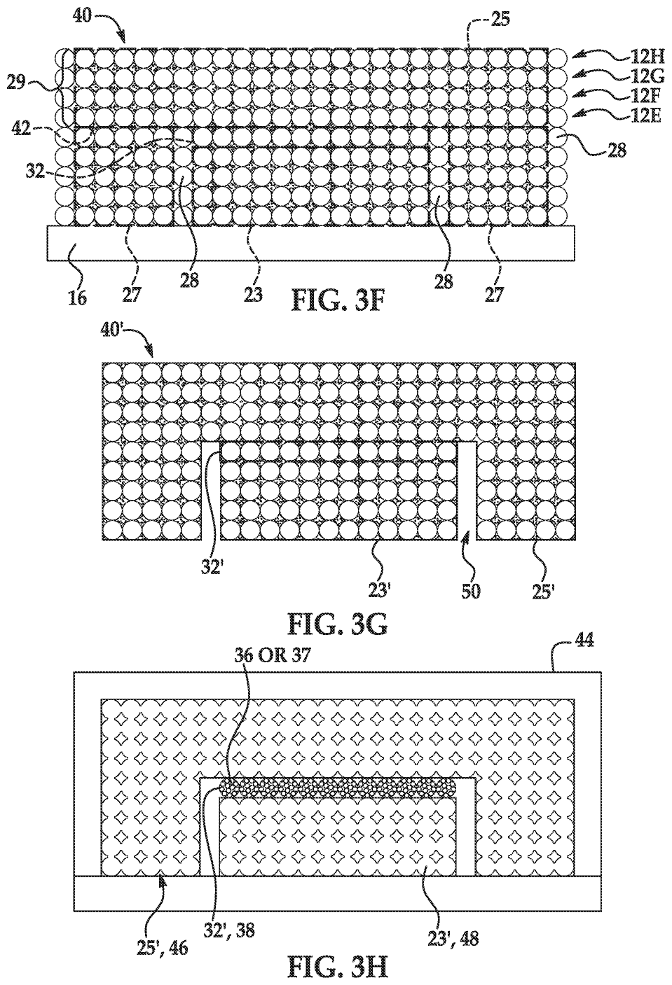

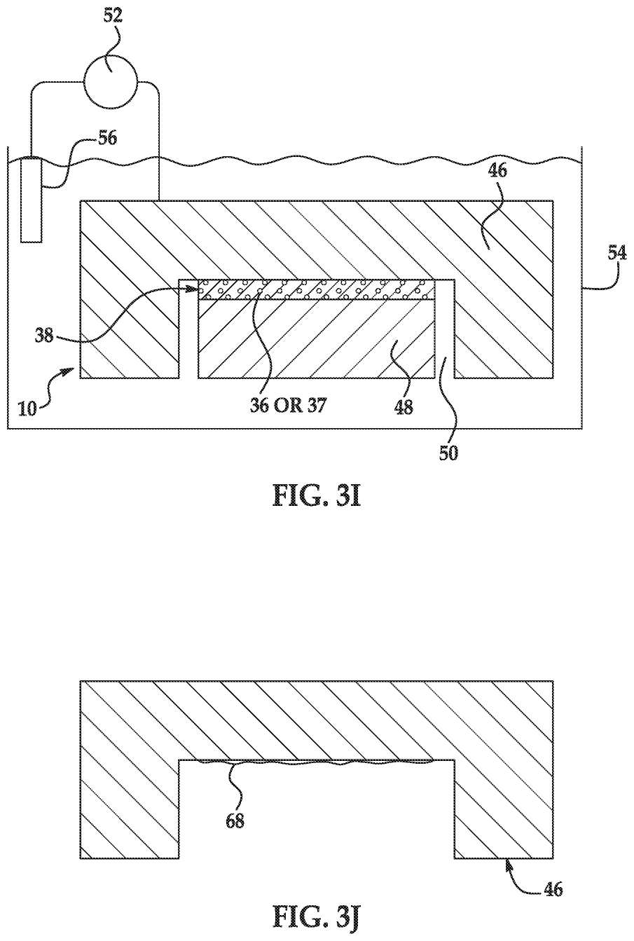

The build material 14 may be spread to form the layers 12, 12A, 12B, etc. on a build area platform 16, and the respective layers 12, 12A, 12B, etc. may be patterned with the binding agent and/or an example of the etch sensitizing liquid functional agent one layer at a time. Examples of the spreading of the build material 14 and the application of the various agents to pattern are described in more detail in reference to FIGS. 3A-3J. The agent(s) used to pattern any individual build material layer 12, 12A, 12B, etc. will depend upon whether the patterned portion is part of the build material support structure 23, the patterned intermediate part 25, or the patterned etchable connection 32. The binding agent is used to pattern the build material support structure 23 and the patterned intermediate part 25, and either i) the binding agent and the separate agent including the etch sensitizer or ii) the combined agent including both the binder and the etch sensitizer is used to pattern the patterned etchable connection 32.

As shown in FIGS. 2A through 2C, the patterned etchable connection 32 is defined between at least a portion of the build material support structure 23 and the patterned intermediate part 25. In these examples, the build material support structure 23 provides support for at least some of the build material 14 of the patterned intermediate part 25 during the patterning process and during the subsequent heating process. Also in these examples, the patterned intermediate part 25 at least partially overlies the build material support structure 23.

In the example shown in FIG. 2A, the patterned etchable connection 32 is built up vertically between one surface of the build material support structure 23 and one surface of the patterned intermediate part 25, and then is curved so that it overlies a portion of the build material support structure 23. In this example, the build material support structure 23 provides support at least for the curved portion of the patterned intermediate part 25. To form this intermediate structure 40A, the binder agent is selectively applied on layers 12 through 12H to define the patterned intermediate part 25; the binder agent is selectively applied on layers 12 through 12D to define the build material support structure 23; and either i) the binding agent and the separate agent including the etch sensitizer or ii) the combined agent is selective applied on layers 12 through 12E to define the patterned etchable connection 32.

In the example shown in FIG. 2B, the patterned etchable connection 32 is horizontally defined between one surface of the build material support structure 23 and one surface of the patterned intermediate part 25. In this example, the patterned etchable connection 32 completely overlies the build material support structure 23, which provides support for the overlying portion of the patterned intermediate part 25. To form this intermediate structure 40B, the binder agent is selectively applied on layers 12 through 12W to define the patterned intermediate part 25; the binder agent is selectively applied on layers 12 through 12R to define the build material support structure 23; and either i) the binding agent and the separate agent including the etch sensitizer or ii) the combined agent is selective applied on layers 12S and 12T to define the patterned etchable connection 32. Also in this example, some of the build material 14 between the patterned intermediate part 25 and the build material support structure 23 remains non-patterned (shown at reference numeral 28). The non-patterned build material 28 can be easily removed after patterning and before heating, and thus can create a space between the patterned intermediate part 25 and the build material support structure 23.

In the example shown in FIG. 2C, the patterned etchable connection 32 is built up vertically between one surface of the build material support structure 23 and a portion of one surface of the patterned intermediate part 25. To form this intermediate structure 40C, the binder agent is selectively applied on layers 12 through 12H to define the patterned intermediate part 25; the binder agent is selectively applied on layers 12C through 12E to define the build material support structure 23; and either i) the binding agent and the separate agent including the etch sensitizer or ii) the combined agent is selective applied on layers 12C through 12E to define the patterned etchable connection 32. Also in this example, some of the build material 14 between the patterned intermediate part 25 and the build material support structure 23 remains non-patterned 28, and thus can create spaces between the patterned intermediate part 25 and the build material support structure 23. In this example, the build material support structure 23, in combination with the non-patterned build material 28, provides support for the overlying portion of the patterned intermediate part 25 formed thereon during patterning.

In the example shown in FIG. 2C, the intermediate structure 40C can be extracted from any non-patterned build material 14, 28 surrounding the structure 40C and in the spaces, and then rotated (e.g., 90°) so that the build material support structure 23 contacts a surface of a heating mechanism and so that the curved center portion of the horseshoe or C-shaped part is substantially parallel to the surface of the heating mechanism. In these examples, the build material support structure 23 provides support for a different portion of the patterned intermediate part 25 during heating than during patterning.

As shown in FIG. 2D, the patterned etchable connection 32 is defined between the build material support structure 23 and the patterned intermediate part 25. In this example, the patterned etchable connection 32 is at least partially perpendicular to the build area platform 16. In this and other similar examples, the build material support structure 23 may be next to the patterned etchable connection 32, which is next to the patterned intermediate part 25 on the build area platform 16. In these examples, there is no non-patterned build material 28 between the build material support structure 23 and the patterned intermediate part 25, and a small portion of the patterned intermediate part 25 overlies the build material support structure 23 during patterning.

In the example shown in FIG. 2D, the intermediate structure 40D can be extracted from any non-patterned build material 14, 28 surrounding the structure 40D, and then rotated (e.g., 90°) so that the build material support structure 23 contacts a surface of a heating mechanism and the patterned etchable connection 32 is at least partially parallel to the surface of the heating mechanism. In these examples, the build material support structure 23 provides support for the patterned intermediate part 25 during heating, and for the small portion of the patterned intermediate part 25 during the printing/patterning process.

Several examples of the intermediate structure 40 and the patterned etchable connection 32 have been illustrated in FIGS. 2A through 2D. It is to be understood that the components 23, 25, 32 of the intermediate structure 40 may have other configurations, as long as the geometry of the irreversibly etchable connection can be etched away to separate the 3D object from the 3D support structure.

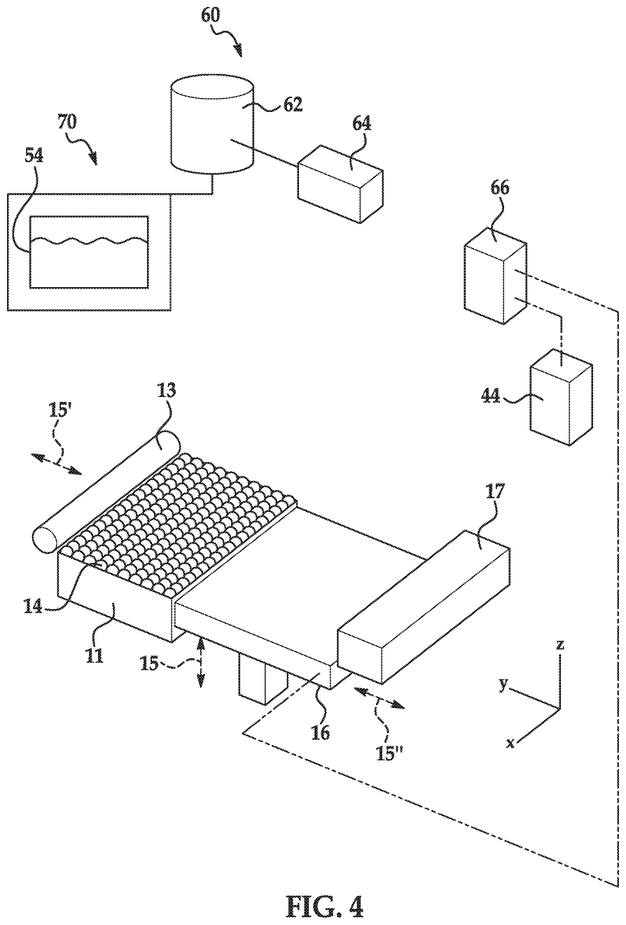

Another, more specific example of the 3D printing method 100 is shown in FIGS. 3A through 3J. Any examples of the build material, the binding agent, and the etch sensitizing liquid functional agent described herein may be used in this example of the method 100. Moreover, the printing system 60, shown in FIG. 4, will be discussed in detail in conjunction with FIGS. 3A through 3J.

In this example of the method, patterning the metallic build material layers includes patterning a first metallic build material layer 12 by selectively applying the binding agent 18 to define: a layer 22 of the build material support structure 23 and a layer 26 of the patterned intermediate part 25 separated by non-patterned metallic build material 28 (see FIGS. 3A and 3B); applying another layer of metallic build material 12A, 12B, 12C, etc. on the patterned first metallic build material layer (FIGS. 3C and 3D); patterning the other layer (e.g., layer 12D) of metallic build material by selectively applying i) the binding agent 18 and the separate agent 21 or ii) the combined agent 19 on a portion of the other layer 12D of metallic build material that overlies the build material support structure 23, thereby forming the patterned etchable connection 32 (FIG. 3E); and selectively applying the binding agent 18 on another portion of the other layer 12D of metallic build material to define an outer layer 23 of a region 27 of the patterned intermediate part 25 (FIGS. 3D-3F); and forming a remaining region 29 of the patterned intermediate part 25 on the patterned etchable connection 32 and in contact with the region 27 of the patterned intermediate part 25, thereby forming the intermediate structure 40 including the patterned intermediate part 25 and the build material support structure 23 temporarily bound together at the patterned etchable connection 32 (FIGS. 3E and 3F).

An example of the patterning of the first metallic build material layer 12 is shown in cross-section in FIGS. 3A and 3B. Prior to patterning, build material particles 14 may be applied to form the layer 12, and then the layer 12 may be patterned. In the example shown in FIG. 3A, one build material layer 12 including build material particles 14 has been deposited on (i.e., applied to, formed on, etc.) the build area platform 16 and patterned.

Forming and patterning the build material layer 12 may include the use of a printing system (an example of which is shown at reference numeral 60 in FIG. 4). The printing system 60 may include the build area platform 16, a build material supply 11 containing build material particles 14, a build material distributor 13, and an applicator 17.

The build area platform 16 receives the build material particles 14 from the build material supply 11. The build area platform 16 may be moved in the directions as denoted by the arrow 15 (FIG. 4), e.g., along the z-axis, so that the build material particles 14 may be delivered to the build area platform 16 or to a previously patterned layer (see, e.g., FIG. 3C). In an example, when the build material particles 14 are to be delivered, the build area platform 16 may be programmed to advance (e.g., downward) enough so that the build material distributor 13 can push the build material particles 14 onto the build area platform 16 to form a substantially uniform build material layer 12 thereon. The build area platform 16 may also be returned to its original position, for example, when a new object is to be built.

The build material supply 11 may be a container, bed, or other surface that is to position the build material particles 14 between the build material distributor 13 and the build area platform 16.

The build material distributor 13 may be moved in the directions as denoted by the arrow 15′ (FIG. 4), over the build material supply 11 and across the build area platform 16 to spread the build material particles 14 over the build area platform 16. The build material distributor 13 may also be returned to a position adjacent to the build material supply 11 following the spreading of the build material particles 14. The build material distributor 13 may be a blade (e.g., a doctor blade), a roller, a combination of a roller and a blade, and/or any other device capable of spreading the build material 16 over the build area platform 16. For instance, the build material distributor 13 may be a counter-rotating roller. In some examples, the build material supply 11 or a portion of the build material supply 11 may translate along with the build material distributor 13 such that build material particles 14 are delivered continuously to the material distributor 13, rather than being supplied from a single location (as shown in FIG. 4).

A controller (shown as 62 in FIG. 4) may process build material supply data, and in response, may control the build material supply 11 to appropriately position the build material particles 14, and may process spreader data, and in response, may control the build material distributor 13 to spread the supplied build material particles 14 over the build area platform 16 to form the build material layer 12 thereon. As shown in FIG. 3A, one build material layer 12 has been formed. The layers 12, 12A, etc. shown in FIGS. 2A through 2D may be formed in a similar manner.

The build material layer 12 has a substantially uniform thickness across the build area platform 16. In an example, the thickness of the build material layer 12 ranges from about 90 μm to about 110 μm, although thinner or thicker layers may be used. For example, the thickness of the build material layer 12 may range from about 50 μm to about 200 μm. In another example, the thickness of the build material layer 12 ranges from about 30 μm to about 300 μm. In yet another example, the thickness of the build material layer 12 may range from about 20 μm to about 500 μm. The layer 12 thickness may be about 2× (i.e., 2 times) the particle diameter at a minimum for finer part definition. In some examples, the layer 12 thickness may be about 1.2× the particle diameter.

A binding agent 18 is selectively applied to different portions of the build material layer 12 in order to pattern the layer 12. The different portions 20, 24 of the build material layer 12 to which the binding agent 18 is selectively applied may be respectively defined by a 3D model of the support structure that is to be formed and a 3D model of the 3D object that is to be formed. In FIG. 3A, the binding agent 18 is selectively applied to the portion/area 20 of the build material layer 12 to define one patterned layer 22 (shown in FIG. 3B) of a build material support structure 23 (shown in FIG. 3D), and the binding agent 18 is selectively applied to the portion(s)/area(s) 24 of the build material layer 12 to define one patterned layer 26 (shown in FIG. 3B) of a patterned intermediate part 25 (shown in FIG. 4F).

The applicator 17 may be used to selectively apply the binding agent 18. The applicator 17 may include nozzles, fluid slots, and/or fluidics for dispensing the binding agent 18. The applicator 17 may be a thermal inkjet printhead or print bar, a piezoelectric printhead or print bar, or a continuous inkjet printhead or print bar. While a single applicator 17 is shown in FIG. 3B, it is to be understood that multiple applicators 17 may be used.

The applicator 17 may be scanned across the build area platform 16, for example, in the directions as denoted by the arrow 15″ in FIG. 4. The applicator 17 may extend a width of the build area platform 16. The applicator 17 may also be scanned along the x-axis, for instance, in configurations in which the applicator 17 does not span the width of the build area platform 16 to enable the applicator 17 to deposit the binding agent 18 over a large area of a build material layer 12. The applicator 17 may thus be attached to a moving XY stage or a translational carriage that moves the applicator 17 adjacent to the build area platform 16 in order to deposit the binging agent 18 in predetermined areas 20, 24 of the build material layer 12.

The applicator 17 may deliver drops of the binding agent 18 at a resolution ranging from about 300 dots per inch (DPI) to about 1200 DPI. In other examples, the applicator 17 may deliver drops of the binding agent 18 at a higher or lower resolution. The drop velocity may range from about 5 m/s to about 24 m/s and the firing frequency may range from about 1 kHz to about 100 kHz. In one example, the volume of each drop may be in the order of about 3 picoliters (pl) to about 18 pl, although it is contemplated that a higher or lower drop volume may be used. In some examples, the applicator 17 is able to deliver variable drop volumes of the binding agent 18. One example of a suitable printhead has 600 DPI resolution and can delivery drop volumes ranging from about 6 pl to about 14 pl.

The binding agent 18 is deposited interstitially in the openings or voids between the build material particles 14. Capillary flow can move the binding agent 18 between the individual build material particles 14 in the areas 20, 24.

In this example, it is desirable for the patterned layers 22, 26 to be separated by non-patterned build material 28, (i.e., particles 14 without any binding agent 18 applied thereto) so that the layers 22, 26 are not in direct contact with one another. The non-patterned build material 28 is not intended to be used in forming the build material support structure 23 or the patterned intermediate part 25. In this example, as shown in FIGS. 3A and 3B, some of the non-patterned build material 28 is located at the outer edges of the patterned layer 26 of the patterned intermediate part 25. The build material particles 14 that are directly adjacent to the edges of the build area platform 16 may be exposed to a different environment (a metal wall, air, etc.) than the build material particles 14 that are surrounded by other build material particles 14. The different environment can lead to non-uniformity at the edges. As such, it may be desirable to have non-patterned build material 28 at the outer edges of the patterned layer 26.

Referring specifically now to FIG. 3B, the selective application of the binding agent 18 onto the build material particles 14 within the area 24 results in the formation of a patterned layer 26, which is to become part of a patterned intermediate part 25 (FIG. 3F), which is ultimately to be sintered to form the 3D object/part. More particularly, in the example shown in FIG. 3B, the patterned layer 26 is the first layer of the 3D object being formed. Similarly, as shown in FIG. 3B, the selective application of the binding agent 18 onto the build material particles 14 within the area 20 results in the formation of a patterned layer 22, which is to become part of the build material support structure 23 (FIG. 3D). More particularly, in the example shown in FIG. 3B, the patterned layer 22 is the first layer of the build material support structure 23 being formed.

In examples of the method where the build material support structure 23 is a single layer, the method 100 may continue with forming the remaining portion 29 of the patterned part 25. In other examples, the build material support structure 23 (FIG. 3D) is a multi-layer structure, and thus the method may further include iteratively applying additional metallic build material layers (e.g., 12A, 12B, 12C, shown in FIG. 3C) and selectively applying the binding agent 18 to the additional build material layers 12A, 12B, 12C to define several layers of the build material support structure 23 and several layers of a region 27 of the patterned intermediate part 25, wherein the several layers of the build material support structure 23 and the several layers of the region 27 of the patterned intermediate part 25 are separated by additional non-patterned build material 28.

FIG. 3C depicts the repeated application of build material particles 14 to form the other build material layers 12A, 12B, 12C and the repeated patterning of these additional build material layers 12A, 12B, 12C over the first layer 12 of patterned build material. As mentioned above and as shown in FIG. 3D, repeated application and patterning may be performed to iteratively build additional layers of the build material support structure 23, as well as additional layers of the region 27 of the patterned intermediate part 25. Repeated application and patterning may be performed until the total number of build material layers 30 that are patterned form a complete build material support structure 23 according to a 3D object model of a 3D support structure 48 (FIG. 3I). As such, the total number of build material layers 30 that are patterned will depend on the desired dimensions of the build material support structure 23 and the ultimately formed 3D support structure 48. In the example depicted in FIGS. 3C and 3D, four build material layers 12, 12A, 12B, 12C are applied and patterned to form the complete build material support structure 23.

As shown in FIGS. 3D and 3E, after the desired total number of build material layers 30 are patterned to form the build material support structure 23, the method continues by applying another layer of build material 12D, and patterning this other build material layer 12D. Patterning the layer 12D may be accomplished by selectively applying (i) the binding agent 18 and a separate agent 21 including an etch sensitizer and not including a binder (i.e., one example of the etch sensitizing liquid functional agent disclosed herein), or (ii) a combined agent 19 including the binder and the etch sensitizer (i.e., another example of the etch sensitizing liquid functional agent disclosed herein) on a portion of the other layer 12D of build material that overlies the build material support structure 23, thereby forming a patterned etchable connection 32 (reference numeral 206); and selectively applying the binding agent 18 on another portion of the other layer 12D of build material to define an outer layer 34 of the region 27 of the patterned intermediate part 25.

Any example of the binding agent 18 described herein may be utilized in combination with any example of the separate etch sensitizing liquid functional agent 21 that does not include a binder in order to define the patterned etchable connection 32. The binder from the binding agent 18 can temporarily bind the build material particles 14 of the patterned etchable connection 32, and the etch sensitizer of the separate etch sensitizing liquid functional agent 21 can form a sensitized product 36 (FIGS. 3H and 3I) within the irreversibly etchable connection 38 (FIG. 3I) during de-binding and/or sintering or can remain (as etch sensitizer 37) within the irreversibly etchable connection 38 after de-binding and sintering.

When the agents 18 and 21 are used to define the patterned etchable connection 32, the binding agent 18 may be dispensed from the applicator 17, and the separate etch sensitizing liquid functional agent 21 may be dispensed from a separate applicator. The separate applicator may be similar to applicator 17 (i.e., may be a thermal inkjet printhead, a piezoelectric printhead, etc.), and may be operated in the same manner as previously described herein. In another example, the applicator 17 may have separate chambers that contain the binding agent 18 and the separate etch sensitizing liquid functional agent 21, and may also have separate printheads, nozzles, etc. to separately and selectively dispense the two agents 18, 21. In these examples, the applicator(s) 17 may be programmed to receive commands from the controller 62 and to deposit the agents 18 and 21 according to a 3D object model of the irreversibly etchable connection 38. In the example shown in FIG. 3D, the applicator(s) 17 sequentially or simultaneously apply the agents 18 and 21 to the build material particles 14 of the layer 12D which overly the build material support structure 23. This defines the patterned etchable connection 32 on a surface of the build material support structure 23. The agents 18 and 21 are deposited interstitially in the openings or voids between the build material particles 14. Capillary flow can move the agents 18 and 21 between the individual build material particles 14 in the layer 12D.

Alternatively, any example of the combined agent 19, including both the binder and the etch sensitizer, may be used to define the patterned etchable connection 32. When the combined agent 19 is used, a separate binding agent 18 is not utilized to define the patterned etchable connection 32. In these examples, the binder from the combined agent 19 can temporarily bind the build material particles 14 of the patterned etchable connection 32, and the etch sensitizer of the combined agent 19 can form a sensitized product 36 (FIGS. 3H and 3I) within the irreversibly etchable connection 38 (FIG. 3I) during de-binding and/or sintering or can remain (as etch sensitizer 37) within the irreversibly etchable connection 38 after de-binding and sintering.

When the combined agent 19 is used to define the patterned etchable connection 32, the combined agent 19 may be dispensed from an applicator that is similar to applicator 17 (i.e., may be a thermal inkjet printhead, a piezoelectric printhead, etc.), and that may be operated in the same manner as previously described herein for the applicator 17. In another example, the applicator 17 may have separate chambers that contain the combined agent 21 and the binding agent 18 (e.g., used to pattern the build material support structure 23 and the patterned intermediate part 25), and may also have separate printheads, nozzles, etc. for separately and selectively dispensing the two agents 19, 18. In these examples, the applicator 17 may be programmed to receive commands from the controller 62 and to deposit the combined agent 19 according to a 3D object model of the irreversibly etchable connection 38. In the example shown in FIG. 3D, the applicator 17 applies the agent 19 to the build material particles 14 of the layer 12D which overly the build material support structure 23. This defines the patterned etchable connection 32 on a surface of the build material support structure 23. The combined agent 19 is deposited interstitially in the openings or voids between the build material particles 14. Capillary flow can move the agent 19 between the individual build material particles 14 in the layer 12D.

Also in the example shown in FIG. 3D, the applicator 17 selectively applies the binding agent 18 on those portion(s) of the build material layer 12D in order to define the outer layer 34 of the region 27 of the patterned intermediate part 25. In these examples, the applicator 17 may be programmed to receive commands from the controller 62 and to deposit the binding agent 18 according to a 3D object model of the 3D object being formed.

As shown in FIGS. 3E and 3F, this example of the method 100 further includes forming a remaining region 29 of the patterned intermediate part 25 on the patterned etchable connection 32 and in contact with the (previously patterned) region 27 of the patterned intermediate part 25, thereby forming an intermediate structure 40 including the patterned intermediate part 25 and the build material support structure 23, temporarily bound together at the patterned etchable connection 32. The remaining region 29 of the patterned intermediate part 25 is formed by applying a further layer 12E of build material on the patterned etchable connection 32 and the outer layer 34 of the region 27 of the patterned intermediate part 25, and selectively applying the binding agent 18 to the further layer 12E to define a patterned layer 42 of the remaining region 29 of the patterned intermediate part 25. This patterned layer 42 of the remaining region 29 is in direct contact with at least some of the region 27, so that the two regions 27, 29 can be sintered together to form the 3D object. Moreover, this patterned layer 42 of the remaining region 29 overlies the patterned etchable connection 32 and the support structure 23, both of which provide physical support to the patterned layer 42 and any other layers applied and patterned to form the remaining region 29.

In examples of the method 100 where the remaining region 29 is a single layer, the method may continue with heating the intermediate structure 40. In other examples, the remaining region 29 (FIG. 3F) is a multi-layer structure, and thus the method 100 may further include iteratively applying additional build material layers (e.g., 12E, 12F, 12G, 12H shown in FIG. 3F) and selectively applying the binding agent 18 to the additional build material layers 12E, 12F, 12G, 12H to define several layers of the remaining region 29 of the patterned intermediate part 25.

After the layer(s) 12E, 12F, 12G, 12H of the remaining region 29 are patterned, the intermediate structure 40 is formed. The intermediate structure 40 is similar to intermediate structures 40A, 40B, 40C, or 40D, in that each of the structures 40, 40A, 40B, 40C, 40D includes the patterned intermediate part 25, the build material support structure 23, and the patterned etchable connection 32 which temporarily binds the patterned intermediate part 25 and the build material support structure 23. As such, the following discussion of evaporation and heating may be applicable for any intermediate structure 40, 40A, 40B, 40C, 40D that may be formed.

In any of the examples disclosed herein, the intermediate structure 40, 40A, 40B, 40C, 40D may be part of a build material cake including the intermediate structure 40, 40A, 40B, 40C, 40D and any non-patterned build material 28. In the example shown in FIG. 3F, the non-patterned build material 28 may be positioned between surfaces of the patterned intermediate part 25 and surfaces of the build material support structure 23 and/or surrounding the patterned intermediate part 25.

During and/or after the formation of the intermediate structure 40, 40A, 40B, 40C, 40D, the liquid components of the binding agent 18, and the separate agent 21 or the combined agent 19 may be at least substantially evaporated to form a densified intermediate part 25′, a densified build material support structure 23′, and a densified patterned etchable connection 23′ (which together make up the densified intermediate structure 40′ shown in FIG. 3G). In some examples, the liquid components (e.g., water, solvents) may be substantially evaporated during the layer by layer patterning process and/or while the intermediate structure 40′ is on the build area platform, and thus a post excavation baking process may not be used. In these examples, additional heating may be used in order to remove water and solvents, which may activate the binder to generate a densified intermediate structure 40′. In other examples, enough of the liquid components may be evaporated during the layer by layer patterning process and/or while the intermediate structure 40′ is on the build area platform to render the structure 40′ handleable, and then a post excavation baking process may be used to remove additional solvent and activate the binder to generate the densified intermediate structure 40′.

It is to be understood that at least substantial evaporation of the liquid components may be partial evaporation or complete evaporation. At least substantial evaporation may be partial evaporation when the presence of residual liquid components does not deleteriously affect the desired structural integrity of the intermediate structure 40 or the final 3D object that is being formed. As an example, the densified intermediate part 25′ formed by the at least substantial evaporation of the liquid components of the agent(s) 18 may contain a residual amount of the liquid components of the agent 18, but the liquid components of the agent 18 are completely removed during subsequent heating.

As mentioned, at least substantial evaporation of the liquid components (e.g., water and solvents) activates the binder in the binding agent 18, and when used, in the combined agent 19. For example, accelerated evaporation and binder activation may occur when heating to temperatures above a glass transition temperature or a minimum film formation temperature of the binder. When activated, the binder coalesces and forms a polymer glue that coats and binds together the build material particles 14 patterned with the binding agent 18, and when used, the combined agent 19. At least substantial evaporation of the liquid components also may result in the densification of the patterned build material particles 14 through capillary compaction. As such, at least substantial evaporation forms the densified intermediate structure 40′, shown in FIG. 3G.

In an example when an acrylic latex is used as the binder, a first solvent of the binding agent 18 and/or combined agent 21 may evaporate and allow a second solvent of the binding agent 18 and/or combined agent 21 to come into contact with and soften the acrylic latex particles. Then, as the second solvent evaporates, the softened acrylic latex particles may merge or coalesce to form the continuous network or film to bind the patterned volumes of build material particles 14 into, for example, a densified intermediate part 25′, a densified build material support structure 23′, and a densified patterned etchable connection 32′ (which together make up the densified intermediate structure 40′ shown in FIG. 3G).

The liquid components may be volatile enough to evaporate at ambient temperature, or the densification/evaporation temperature may be above ambient temperature. As used therein, “ambient temperature” may refer to room temperature (e.g., ranging about 18° C. to about 22° C.), or to the temperature of the environment in which the 3D printing method is performed (e.g., the temperature of the build area platform 16 during the forming and patterning of new layers). The temperature of the environment in which the 3D printing method is performed (e.g., the temperature of the build area platform 16 during the forming and patterning of new layers) is about 5° C. to about 50° C. below the boiling point of the agent 18 and 19 or 21. In an example, the temperature of the build area platform 16 during the forming and patterning of new layers ranges from about 50° C. to about 95° C. Other examples of the 3D printing environment temperature may range from about 40° C. to about 65° C. The densification/evaporation temperature may also be below a temperature at which the binder would be damaged (i.e., be unable to bind). For a majority of suitable binders, the upper limit of the densification/evaporation temperature ranges from about 180° C. to about 220° C. Above this temperature threshold, the binder would chemically degrade into volatile species and leave the patterned components 23, 25, 32, and thus would stop performing their function. For some agents 18, and when used 19, the densification/evaporation temperature ranges from about 50° C. to about 220° C. As still another example, the densification/evaporation temperature may range from about 70° C. to about 90° C.

As the liquid components evaporate, the etch sensitizer (in the patterned etchable connection 32) can precipitate out and collect across the surfaces of the build material particles 14 in the patterned etchable connection 32.

In some examples of the method 100, the liquid components of the binding agent 18, and when used, the combined agent 19, may be allowed to evaporate without heating. For example, more volatile solvents can evaporate in seconds at ambient temperature. In these examples, the build material cake is not exposed to heat or radiation to generate heat, and the water and/or solvent(s) in the binding agent 18, and when used, in the combined agent 19 evaporate(s) over time. In an example, the water and/or solvent(s) in the binding agent 18, and when used, the combined agent 19 may evaporate without heating within a time period ranging from about 1 second to about 1 minute.

In other examples of the method 100, the intermediate structure 40, 40A, 40B, 40C, 40D may be heated to an evaporation temperature at a rate of about 1° C./minute to about 10° C./minute, although it is contemplated that a slower or faster heating rate may be used. The heating rate may depend, in part, on one or more of: the agents 18, 19, 21 used, the size (i.e., thickness and/or area (across the x-y plane)) of the layers, and/or the characteristics of the structure 40, 40A, 40B, 40C, 40D (e.g., size, wall thickness, etc.). In an example, intermediate structure 40, 40A, 40B, 40C, 40D is heated to the densification/evaporation temperature at a rate of about 2.25° C./minute.

At least substantially evaporating (with or without heating) activates the binder, and the activated binder provides enough adhesive strength to hold the densified intermediate structure 40′ together with enough mechanical stability to survive removal from the build material cake. As such, the densified intermediate structure 40′ exhibits handleable mechanical durability, and is capable of being separated from the non-patterned build material 28. FIG. 3G depicts the densified intermediate structure 40′ after the non-patterned build material 28 has been removed.

If after excavation from the build area platform 16, the densified intermediate structure 40′ still contains an undesirable amount of less-volatile solvent(s), the post-excavation baking may be performed at a temperature that will evaporate these solvent(s).

While not shown, it is to be understood that the intermediate structures 40A, 40B, 40C, 40D may be densified in a similar manner.

The densified intermediate structure 40′ may be extracted from the build material cake or separated from the non-patterned build material 28 by any suitable means. In an example, the densified intermediate structure 40′ may be extracted by lifting the densified intermediate structure 40′ from the non-patterned build material 28. Any suitable extraction tool may be used. In some examples, the densified intermediate structure 40′ may be cleaned to remove non-patterned build material 28 from its surface. In an example, the densified intermediate structure 40′ may be cleaned with a brush and/or an air jet, may be exposed to mechanical shaking, or may be exposed to other techniques that can remove the non-patterned build material 28. As shown in FIG. 3G, removal of the non-patterned build material 28 can expose outer edges of the densified intermediate structure 40′ and any spaces 50 between the densified build material support structure 23′ and portions of the densified patterned intermediate part 25′ that had been occupied by the non-patterned build material 28 during the printing process.

When the densified intermediate structure 40′ is extracted from the build material cake and/or cleaned of the non-patterned build material 28, the densified intermediate structure 40′ may be removed from the build area platform 16 and placed in a heating mechanism 44 (as shown in FIG. 3H).

The heating mechanism 44 may be used to perform a heating sequence. In some examples, the heating sequence involves exposing the intermediate structure 40′ (or the densified version of the intermediate structures 40A, 40B, 40C, or 40D) to a temperature that decomposes the etch sensitizer to a decomposition product that reacts to generate sensitized product(s) 36 in the patterned etchable connection 32. In some examples, the heating sequence involves exposing the intermediate structure 40′ (or the densified version of the intermediate structures 40A, 40B, 40C, or 40D) to temperatures for de-binding and sintering, at which the etch sensitizer is non-reactive, so that the etch sensitizer 37 remains in the patterned etchable connection 32. The heating sequence may form a 3D particle article 10, as shown in FIG. 3I. In some examples, heating involves exposure to a series of temperatures that form a 3D object 46 from the patterned intermediate part 25, 25′, a 3D support structure 48 from the build material support structure 23, 23′ and the irreversibly etchable connection 38 from the patterned etchable connection 32, 32′, the irreversibly etchable connection 38 including the sensitized product(s) 36 or the etch sensitizer 37 and being positioned between the 3D object 46 and the 3D support structure 48.

In some examples, the series of temperatures may involve heating the (densified) intermediate structure 40′ (or the densified version of the intermediate structures 40A, 40B, 40C, or 40D) to a de-binding temperature, and then to a sintering temperature, wherein a sensitized product formation temperature is reached during the exposure to the series of temperatures. Briefly, the de-binding temperature removes the binder from the densified intermediate structure 40′ to produce an at least substantially binder-free intermediate structure, and the at least substantially binder-free intermediate structure may be sintered at the various temperatures to form the final 3D object 46 and the 3D support structure 48. The temperature for de-binding is lower than the temperatures for sintering. In these examples, the temperature for sensitization (i.e., sensitized product formation), and thus for the formation of the irreversibly etchable connection 38, may take place at different temperatures, which depends upon the etch sensitizer used.

In other examples, the series of temperatures may involve heating the (densified) intermediate structure 40′ (or the densified version of the intermediate structures 40A, 40B, 40C, or 40D) to a de-binding temperature, and then to a sintering temperature, wherein the etch sensitizer is non-reactive at both the de-binding temperature and the sintering temperature. Briefly, the de-binding temperature removes the binder from the densified intermediate structure 40′ to produce an at least substantially binder-free intermediate structure, and the at least substantially binder-free intermediate structure may be sintered at the various temperatures to form the final 3D object 46 and the 3D support structure 48. In these examples, etch sensitizer 37 remains in the irreversibly etchable connection 38.

Heating to de-bind is accomplished at a thermal decomposition temperature that is sufficient to thermally decompose the binder. As such, the temperature for de-binding depends upon the binder in the agents 18, 19 used. In an example, the thermal decomposition temperature ranges from about 250° C. to about 800° C. In another example, the thermal decomposition temperature ranges from about 300° C. to about 550° C. The binder may have a clean thermal decomposition mechanism (e.g., leaves non-volatile residue in an amount <5 wt % of the initial binder, and in some instances non-volatile residue in an amount <1 wt % of the initial binder). The smaller residue percentage (e.g., close to 0%) is more desirable. During the de-binding stage, the binder decomposes first into a liquid phase of lower viscosity. Evaporation of this liquid may initially increase the open porosity in the substantially binder-free intermediate structure.

While not being bound to any theory, it is believed that the at least substantially binder-free intermediate structure may maintain its shape due, for example, to one or more of: i) the low amount of stress experienced by the at least substantially binder-free i part due to it not being physically handled, and/or ii) low level necking occurring between the build material particles 14 at the thermal decomposition temperature of the binder. The at least substantially binder-free intermediate structure may maintain its shape although the binder is at least substantially removed and the build material particles 14 are not yet sintered.

The temperature may then be raised to sinter the substantially binder-free intermediate structure.

Sintering may be performed in stages, where the initial, lower sintering temperatures can result in the formation of weak bonds that are strengthened during final sintering. The initial sintering temperature may be selected to further densify the substantially binder-free intermediate structure and to decrease or eliminate the open porosity throughout the substantially binder-free intermediate structure. The initial sintering temperature may be well above the de-binding temperature, and may be capable of softening the build material particles 14. The initial sintering temperature may thus be dependent upon the build material used. Moreover, the initial sintering temperature may also be dependent on the sintering rate of build material. For example, metal powders with a smaller particle size can be sintered at a higher rate at lower temperatures than the same metal powders with a larger particle size.

During final sintering, the build material particles 14 continue to coalesce to form the 3D object 46 and the 3D support structure 48, and so that a desired density of at least the 3D object 46 is achieved. The final sintering temperature is a temperature that is sufficient to sinter the remaining build material particles 14. The sintering temperature is highly depending upon the composition of the build material particles. During final sintering, the at least substantially binder-free intermediate structure may be heated to a temperature ranging from about 80% to about 99.9% of the melting point(s) of the build material particles 14. In another example, the at least substantially binder-free intermediate structure may be heated to a temperature ranging from about 90% to about 95% of the melting point(s) of the build material particles 14. In still another example, the at least substantially binder-free intermediate structure may be heated to a temperature ranging from about 60% to about 90% of the melting point(s) of the build material particles 14. In still another example, the final sintering temperature may range from about 10° C. below the melting temperature of the build material particles 14 to about 50° C. below the melting temperature of the build material particles 14. In still another example, the final sintering temperature may range from about 100° C. below the melting temperature of the build material particles 14 to about 200° C. below the melting temperature of the build material particles 14. The final sintering temperature may also depend upon the particle size and time for sintering (i.e., high temperature exposure time). As an example, the sintering temperature may range from about 500° C. to about 1800° C. In another example, the sintering temperature is at least 900° C. An example of a final sintering temperature for bronze is about 850° C., and an example of a final sintering temperature for stainless steel is about 1400° C., and an example of a final sintering temperature for aluminum or aluminum alloys may range from about 550° C. to about 620° C. While these temperatures are provided as final sintering temperature examples, it is to be understood that the final sintering temperature depends upon the build material particles that are utilized, and may be higher or lower than the provided examples. Heating at a suitable final sintering temperature sinters and fuses the build material particles 14 to form a completed 3D object 46 and a completed 3D support structure 48, each of which may be even further densified relative to the corresponding components of the at least substantially binder-free intermediate structure. For example, as a result of final sintering, the density may go from 50% density to over 90%, and in some cases very close to 100% of the theoretical density.

When the etch sensitizer is decomposable, at some point during the heating sequence, the temperature for forming the sensitized product is reached. At this temperature, the etch sensitizer thermally decomposes and the decomposition product diffuses throughout the patterned etchable connection 23. The diffused decomposition product reacts with one or more components of the build material in the patterned breakable connection 32 to form the sensitized product 36 at the patterned breakable connection 32 and in the irreversibly breakable connection 38. The sensitized product 36 may be intermetallics (e.g., carbides, nitrides, etc.) that are more susceptible to etching than the metallic build material.

The temperature for sensitized product formation depends upon the etch sensitizer used. For some examples of the etch sensitizer, decomposition and reaction may take place during de-binding. For other examples of the etch sensitizer, decomposition and reaction may take place during sintering. As such, while the heating sequence forms the irreversibly etchable connection 38; it is to be understood that the transformation from the patterned etchable connection 23 to the irreversibly etchable connection 38 may take place at different points in the heating sequencing depending upon the etch sensitizer used.

The following are some other examples of suitable etch sensitizers and their corresponding sensitized product formation temperatures. Sodium hexacyanoferrate decomposes to release carbon and nitrogen species that can react, for example, with chromium in the metallic build material 14, to form chromium carbides and nitrides at about 800° C. (e.g., which may be a de-binding or an initial sintering temperature).

When the etch sensitizer is non-reactive, the temperatures used in the heating sequence do not decompose the etch sensitizer. As such, the etch sensitizer remains in the patterned breakable connection 32 to form the irreversibly breakable connection 38. The etch sensitizer 37 may be are more susceptible to etching than the metallic build material. An example of a non-reactive etch sensitizer is potassium chloride.

The heating sequence may take place in an environment/atmosphere that is compatible with the etch sensitizer and build material used to form the patterned etchable connection 32. As one example, a hydrogen gas (H₂) environment may be used during the heating of some stainless steels (e.g., SS 17-4PH), in order to reduce or prevent carburization. As another example, a mixture of 1% hydrogen gas and an inert gas (argon) may be used during the heating of other stainless steels (e.g., SS 316L, SS 430L, etc.), in order to reduce or prevent carburization. In either example, the hydrogen gas containing environment may help to maintain a reducing environment that favors formation of non-oxide chromium binaries. The gas flow during heating may be at a rate of about 40 cc/min at room temperature and atmospheric pressure. However, it is to be understood that the gas flow rate may be dependent upon the etch sensitizer, the metallic build material, the geometry of the intermediate structure 40, the ramp rate of the heating mechanism 44, etc.

FIG. 3H illustrates the intermediate structure 40′ during heating to the sensitized product formation temperature or to a temperature at which the etch sensitizer is non-reactive. As depicted, the build material particles 14 have begun to coalesce in each of the densified patterned intermediate part 25′, the densified build material support structure 23′, and the densified patterned etchable connection 32′. As such, the formation of the 3D object/part 46, the 3D support structure 48, and the irreversibly etchable connection 38 has been initiated. In some examples within the densified patterned etchable connection 32′, the etch sensitizer has begun to decompose, and the decomposition product has diffused and reacted to form the sensitized product 36. In other examples within the densified patterned etchable connection 32′, the etch sensitizer is non-reactive and remains in the irreversibly etchable connection 38 as the etch sensitizer 37.

The length of time at which the heat (for each of de-binding, in some instances sensitized product generation, and sintering) is applied and the rate at which the structure is heated may be dependent, for example, on one or more of: characteristics of the heating mechanism 44, characteristics of the binder, characteristics of the build material particles (e.g., metal type, particle size, etc.), characteristics of the etch sensitizer, and/or the characteristics of the 3D object/part 46 (e.g., wall thickness).

The densified intermediate structure 40′ (or the densified version of the intermediate structures 40A, 40B, 40C, or 40D) may be heated at the de-binding temperature for a time period ranging from about 10 minutes to about 72 hours. When the structure 40′ contains open porosity to vent out binder pyrolysis, and/or the amount of the binder in the densified intermediate structure 40′ is low (e.g., from about 0.01 wt % to about 4.0 wt % based on the total weight of the intermediate structure 40′), and/or the wall thickness of the structure 40′ is relatively thin, the time period for de-binding may be 3 hours (180 minutes) or less. Longer times may be used if the structure 40′ has less open porosity, if the structure 40′ has thicker walls, and/or if the structure 40′ has a higher concentration of binder. In an example, the de-binding time period is about 60 minutes. In another example, the de-binding time period is about 180 minutes. The densified green part may be heated to the de-binding temperature at a rate ranging from about 0.5° C./minute to about 20° C./minute. The heating rate may depend, in part, on one or more of: the amount of the binder in the densified intermediate structure 40′, the porosity of the densified intermediate structure 40′, and/or the characteristics of the densified intermediate structure 40′.

The at least substantially binder-free intermediate structure may be heated at the sintering temperature(s) for respective time periods ranging from about 20 minutes to about 15 hours. In an example, each time period is 60 minutes. In another example, each time period is 90 minutes. The at least substantially binder-free intermediate structure may be heated to each of the initial sintering temperature and the final sintering temperature at a rate ranging from about 1° C./minute to about 20° C./minute.

In a specific example, the at least substantially binder-free intermediate structure is heated to the de-binding temperature (e.g., 450° C.) at a rate of 0.5° C./minute, and then is held at this temperature for about 180 minutes; and then the temperature is raised to about 800° C. at a rate of 2.5° C./minute and held at this temperature for about 360 minutes. In this example, the etch sensitizer decomposition and reaction takes place at the 800° C. temperature, to form the sensitized product(s) 36. The temperature may then be raised to a sintering temperature (e.g., about 1350° C.) at a rate of about 2.5° C./minute. The sintering temperature may be held for about 240 minutes. It is to be understood that this heating sequence is one example. As discussed herein in some examples, the sensitization reaction between the etch sensitizer decomposition product and the build material component may take place during de-binding and/or during sintering, and thus any of the rates and/or times for these processes may be suitable for the formation of the sensitized product(s) 36.

An example of the resulting 3D printed article 10 is shown in FIG. 3I. After heating, the 3D printed article 10 may be cooled. It is to be understood that the sensitized product(s) 36 or the remaining etch sensitizer 37 remain in the irreversibly etchable connection 38 when cooled.

The 3D printed article 10 includes a first metallic object (e.g., the 3D object 46), a second metallic object (e.g., the 3D support structure 48), and the irreversibly etchable connection 38 between the first and second metallic objects 46, 48, wherein the irreversibly etchable connection 38 includes the sensitized product 36 or the remaining etch sensitizer 37 that preferentially etches relative to the first and second metallic objects 46, 48.

The sensitized product(s) 36 or the remaining etch sensitizer 37 is/are localized to the irreversibly etchable connection 38, and thus add etchant susceptibility to the irreversibly etchable connection 38. As such, the irreversibly etchable connection 38 provides a junction between the first metallic object (e.g., the 3D object 46) and the second metallic object (e.g., the 3D support structure 48) that etches faster than either of the two objects 46, 48. Upon exposure to an etching process, the irreversibly etchable connection 38 will etch away, and the 3D objects 46, 48 will remain substantially intact. The etching property of the irreversibly etchable connection 38 is self-limiting because once the sensitized product 36 or remaining etch sensitizer 37 is etched away, the etching steps.

FIG. 3I illustrates the 3D printed article 10 in an etching bath 54. Examples of the etchant may be selected from the group consisting of a nitric acid solution, an ammonium persulfate solution, a nitroxyl solution, a picric acid solution, and a chromium trioxide solution.

In some examples, the etchant used will depend, in part, on the sensitized product 36 that is formed (and thus depends on the metallic build material 14 and the etch sensitizer used). In these examples, the etchant is selected from the group consisting of a nitric acid solution, an ammonium persulfate solution, a nitroxyl solution, a picric acid solution, and a chromium trioxide solution. For an iron-containing steel build material, a suitable nitric acid solution may include a 1:3 HNO₃:H₂O solution; or from about 10 mL to about 15 mL of HNO₃ in about 85 mL to about 90 mL of H₂O or alcohol. For an iron-containing steel build material, a suitable nitroxyl solution may include from about 1% to about 6% HNO in alcohol (with or without 1% benzalkonium chloride). For a stainless steel build material, a suitable nitric acid solution may include about 20 mL of HNO₃ and about 20 mL of ethylene glycol in about 100 mL of ethanol. For an iron-containing steel build material, a suitable ammonium persulfate solution may include about 10 g of ammonium persulfate in about 90 mL of H₂O. For a nitriding steel build material, a suitable ammonium persulfate solution may include about 15 mL of ammonium persulfate in about 85 mL of H₂O; or about 109 g of ammonium persulfate and 1 g of a wetting agent in about 250 mL of H₂O with about 10 drops of a saturated aqueous sodium thiocyanate solution. For an iron build material, a suitable picric acid solution may include about 4% picric acid in alcohol (with or without 1% benzalkonium chloride). For an iron-containing low alloy steel build material, a suitable picric acid solution may include about 2 g of picric acid and about 25 g sodium hydroxide in about 100 mL of H₂O, or a saturated picric acid solution with a small amount of a wetting agent. For an austenitic stainless steel build material, a suitable chromium trioxide solution may include about 10 g CrO₃ in about 90 mL of H₂O.

In other examples, the etchant used will depend, in part, on the etch sensitizer 37 that remains.

The etchant and the printed article 10 are placed in the etching bath 54. During etching, current flows from a current source 52 into the part 10 to be etched (with the part 10 as the working electrode), through the etchant as ion transport, then returns through the cathode counter electrode 56. The cathode counter electrode 56 may be, for example, a 6 mm diameter 3 cm long graphite rod. This electrode 56 may be suitable for preferentially etching a printed article 10 that is 3 cm on all sides. Sizing and selecting a counter electrode 56 for electrically assisted etching is known in the art.

The irreversibly etchable connection 38 will preferentially etch, while the 3D object 46 and the 3D support structure 48 remain substantially intact. Due to impurities and inhomogeneity in the 3D object 46 and/or the 3D support structure 48, there may be some small degree of etching in undesired areas, i.e. the portion of the objects 46, 48 without the sensitized product(s) 36 or the remaining etch sensitizer 37.

Once etching is complete, the first and second objects 46, 48 may be separated due to the connection 38 being etched away. Alternatively, the first and second objects 46, 48 may remain connected after etching. However, since the sensitized product(s) 36 or remaining etch sensitizer 37 is etched away, the junction is weakened and can be easily broken. As such, the second object (e.g., the 3D support structure 48) can be easily removed from the first object (e.g., the 3D object 46) by breaking the now etched, irreversibly etchable connection 38. Breaking may be accomplished with human hands, or with simple tools, such as pliers and/or a vise. Cutting tools may be used, but may not have to be used in order to break the second object (e.g., the 3D support structure 48) from the first object (e.g., the 3D object 46).

Once separated, the 3D object 46 may be brushed clean, sonicated in a solution of 1:1 volume isopropanol and water, and then dried; or exposed to post-printing polishing, etc.

An example of the 3D object 46 after the irreversibly etchable connection 38 has been etched or etched and broken is depicted in FIG. 3J. At most, some remnants 68 of metal pieces from the irreversibly etchable connection 38 may remain attached to the 3D object 46.

Printing System

Referring now to FIG. 4, an example of the 3D printing system 60 that may be used to perform examples of the method 100 disclosed herein is depicted. It is to be understood that the 3D printing system 10 may include additional components (some of which are described herein) and that some of the components described herein may be removed and/or modified. Furthermore, components of the 3D printing system 60 depicted in FIG. 4 may not be drawn to scale and thus, the 3D printing system 60 may have a different size and/or configuration other than as shown therein.

In an example, the three-dimensional (3D) printing system 60, comprises: a supply 11 of build material particles 14; a build material distributor 13; a supply of a binding agent 18 and a supply of a separate etch sensitizing liquid functional agent 21, or a supply of a combined agent 19; applicator(s) 17 for selectively dispensing the binding agent 18 and the separate etch sensitizing liquid functional agent 21 or the combined agent 19; a controller 62; and a non-transitory computer readable medium having stored thereon computer executable instructions to cause the controller 62 to cause the printing system to perform some or all of the method disclosed herein.

As mentioned above, the build area platform 16 receives the build material particles 14 from the build material supply 11. The build area platform 16 may be integrated with the printing system 60 or may be a component that is separately insertable into the printing system 60. For example, the build area platform 16 may be a module that is available separately from the printing system 60. The build area platform 16 that is shown is one example, and could be replaced with another support member, such as a platen, a fabrication/print bed, a glass plate, or another build surface.

While not shown, it is to be understood that the build area platform 16 may also include built-in heater(s) for achieving and maintaining the temperature of the environment in which the 3D printing method is performed.

Also as mentioned above, the build material supply 11 may be a container, bed, or other surface that is to position the build material particles 14 between the build material distributor 13 and the build area platform 16. In some examples, the build material supply 11 may include a surface upon which the build material particles 14 may be supplied, for instance, from a build material source (not shown) located above the build material supply 11. Examples of the build material source may include a hopper, an auger conveyer, or the like. Additionally, or alternatively, the build material supply 11 may include a mechanism (e.g., a delivery piston) to provide, e.g., move, the build material particles 14 from a storage location to a position to be spread onto the build area platform 16 or onto a previously patterned layer.

As shown in FIG. 4, the printing system 60 also the build material distributor 18 and the applicator(s) 17, both of which have been described in reference to the method 200.

Each of the previously described physical elements may be operatively connected to the controller 62 of the printing system 60. The controller 62 may process print data that is based on a 3D object model of the 3D object/part 46 and of the 3D support structure 48 to be generated. In response to data processing, the controller 62 may control the operations of the build area platform 16, the build material supply 11, the build material distributor 13, and the applicator(s) 17. As an example, the controller 62 may control actuators (not shown) to control various operations of the 3D printing system 62 components. The controller 60 may be a computing device, a semiconductor-based microprocessor, a central processing unit (CPU), an application specific integrated circuit (ASIC), and/or another hardware device. Although not shown, the controller 62 may be connected to the 3D printing system 60 components via communication lines.

The controller 62 manipulates and transforms data, which may be represented as physical (electronic) quantities within the printer's registers and memories, in order to control the physical elements to create the printed article 10. As such, the controller 62 is depicted as being in communication with a data store 64. The data store 64 may include data pertaining to a 3D object 46, a 3D support structure 48, and an irreversibly etchable connection 38 to be printed by the 3D printing system 60. The data for the selective delivery of the build material 16, the binding agent 18, the etch sensitizing liquid functional agent 19 or 21, etc. may be derived from a model of the components 46, 48 and 38 to be formed. For instance, the data may include the locations on each build material layer 12, etc. that the applicator 17 is to deposit the binding agent 18. In one example, the controller 62 may use the data to control the applicator 17 to selectively apply the binding agent 18. The data store 64 may also include machine readable instructions (stored on a non-transitory computer readable medium) that are to cause the controller 62 to control the amount of build material particles 14 that is supplied by the build material supply 11, the movement of the build area platform 16, the movement of the build material distributor 13, the movement of the applicator 17, etc.

As shown in FIG. 4, the printing system 60 also includes the heating mechanism 44. Examples of the heating mechanism 44 include a conventional furnace or oven, a microwave, or devices capable of hybrid heating (i.e., conventional heating and microwave heating). As shown in FIG. 4, the heating mechanism 44 may be a module that is available separately from the printing system 60. In other examples, the heating mechanism 44 may be integrated with the printing system 60.

The heating mechanism 44 and/or the heater(s) in the build area platform 16 may be operatively connected to a driver, an input/output temperature controller, and temperature sensors, which are collectively shown as heating system components 66. The heating system components 66 may operate together to control the heating mechanism 44 and/or the heater(s) in the build area platform 16. The temperature recipe (e.g., heating exposure rates and times) may be submitted to the input/output temperature controller. During heating, the temperature sensors may sense the temperature of the build material particles 14 on the platform 16 or in the intermediate structure 40, 40′, and the temperature measurements may be transmitted to the input/output temperature controller. For example, a thermometer associated with the heated area can provide temperature feedback. The input/output temperature controller may adjust the heating mechanism 44 and/or the heater(s) in the build area platform 16 power set points based on any difference between the recipe and the real-time measurements. These power set points are sent to the drivers, which transmit appropriate voltages to the heating mechanism 44 and/or the heater(s) in the build area platform 16. This is one example of the heating system components 66, and it is to be understood that other heat control systems may be used. For example, the controller 62 may be configured to control the heating mechanism 44 and/or the heater(s) in the build area platform 16.

Examples of the printing system 60 may also include a part finishing system 70. This system 70 includes the etching bath 54. This system 70 may also include a submerging apparatus to receive the printed article 10, and the etching bath 54 can removably receive the submerging apparatus (with the printed article 10 therein). The controller 62 is operatively connected to the submerging apparatus, where the controller 62 is to receive or determine an input time for the printed article 10 and to control submersion of the submerging apparatus (containing the printed article 10) into the etching bath 54 for the input time. The controller 62 may also operate the current source 52 for the input time in order to perform the etching process.

Printing Kit

The components (e.g., build material 14, binding agent 18 and separate agent 21, or build material 14, binding agent 18, and combined agent 19) disclosed herein may be part of a 3D printing kit. The components of the kit may be maintained separately until used together in examples of the 3D printing method disclosed herein. As used herein, “material set” or “kit” is understood to be synonymous with “composition.” Further, “material set” and “kit” are understood to be compositions comprising one or more components where the different components in the compositions are each contained in one or more containers, separately or in any combination, prior to and during printing but these components can be combined together during printing. The containers can be any type of a vessel, box, or receptacle made of any material.

To further illustrate the present disclosure, a prophetic example is given herein. It is to be understood that this prophetic example is provided for illustrative purposes and are not to be construed as limiting the scope of the present disclosure.

### Prophetic Example

Table 4 illustrates examples of etch sensitizers that can be included in an separate or combined agent that can be inkjetted on a corresponding build material in order to form the patterned etchable connection, and ultimately the irreversibly etchable connection. As shown, some of the etch sensitizers can react to form a sensitized product, and another of the etch sensitizers remains in the irreversibly patterned connection that is to be formed after sintering. Table 4 also illustrates an etchant that can be used to selectively etch the irreversibly etchable connection.

TABLE 4

| | | Host Metal | | Sensitized | |
|---|---|---|---|---|---|
| Prophetic | | Sintering | | Product | |
| Example # | Build Material | Temp. ° C. | Etch Sensitizer | Formed? | Etchant |
| 1 | stainless | ~1,100- | sodium or | Yes - | nitric |
| | steel* | 1,500 | potassium | chromium | acid |
| | | | hexacyanoferrate | carbide and | solution |
| | | | | chromium | |
| | | | | nitride | |
| 2 | nickel-based | ~1,100- | sodium or | Yes - | nitric |
| | superalloys** | 1,300 | potassium | chromium | acid |
| | | | hexacyanoferrate | carbide and | solution |
| | | | | chromium | |
| | | | | nitride | |

*commercially available examples include those of the 300 series, such as SS 304, SS 316, and SS 316L, and those of the 400 series, such as SS 420 and SS 430
**a commercially available example includes INCONEL ® 720

It is to be understood that the ranges provided herein include the stated range and any value or sub-range within the stated range, as if the value(s) or sub-range(s) within the stated range were explicitly recited. For example, from about 500° C. to about 3500° C. should be interpreted to include not only the explicitly recited limits of from about 500° C. to about 3500° C., but also to include individual values, such as about 990° C., 1000.5° C., 2055° C., 2750° C., etc., and sub-ranges, such as from about 700° C. to about 3250° C., from about 925° C. to about 2500° C., from about 1020° C. to about 2020° C., etc. Furthermore, when “about” is utilized to describe a value, this is meant to encompass minor variations (up to +/−10%) from the stated value.

Reference throughout the specification to “one example”, “another example”, “an example”, and so forth, means that a particular element (e.g., feature, structure, and/or characteristic) described in connection with the example is included in at least one example described herein, and may or may not be present in other examples. In addition, it is to be understood that the described elements for any example may be combined in any suitable manner in the various examples unless the context clearly dictates otherwise.

While several examples have been described in detail, it is to be understood that the disclosed examples may be modified. Therefore, the foregoing description is to be considered non-limiting.

What is claimed is:

1. A method for three-dimensional (3D) printing, comprising:
patterning metallic build material layers to form an intermediate structure, the patterning including:
selectively applying a binding agent to define: a build material support structure and a patterned intermediate part; and
selectively applying i) the binding agent and a separate agent including a an etch sensitizer or ii) a combined agent including a binder and the etch sensitizer to define a patterned etchable connection between at least a portion of the build material support structure and at least a portion of the patterned intermediate part; and
heating the intermediate structure.

2. The method as defined in claim 1 wherein the heating involves exposure to a series of temperatures that form a 3D printed article including:
a 3D object from the patterned intermediate part;
a 3D support structure from the build material support structure; and
an irreversibly etchable connection from the patterned etchable connection, the irreversibly etchable connection including a sensitized product or the etch sensitizer and being positioned between the 3D object and the 3D support structure.

3. The method as defined in claim 2 wherein the heating involves:
heating the intermediate structure to a de-binding temperature;
and then heating the intermediate structure to a sintering temperature;
and wherein a sensitized product formation temperature is reached during the exposure to the series of temperatures.

4. The method as defined in claim 2, further comprising exposing the 3D printed article to an etchant that preferentially etches the irreversibly etchable connection relative to the 3D object and the 3D support structure.

5. The method as defined in claim 4 wherein the etchant is selected from the group consisting of a nitric acid solution, an ammonium persulfate solution, a nitroxyl solution, a picric acid solution, and a chromium trioxide solution.

6. The method as defined in claim 1 wherein the patterned intermediate part at least partially overlies the build material support structure.

7. The method as defined in claim 1 wherein patterning the metallic build material layers includes:
patterning a first metallic build material layer by selectively applying the binding agent to define: a layer of the build material support structure and a layer of the patterned intermediate part separated by non-patterned metallic build material;
applying an other layer of metallic build material on the patterned first metallic build material layer;
patterning the other layer of metallic build material by:
selectively applying i) the binding agent and the separate agent or ii) the combined agent on a portion of the other layer of metallic build material that overlies the build material support structure, thereby forming the patterned etchable connection; and
selectively applying the binding agent on an other portion of the other layer of metallic build material to define an outer layer of a region of the patterned intermediate part; and
forming a remaining region of the patterned intermediate part on the patterned etchable connection and in contact with the region of the patterned intermediate part, thereby forming the intermediate structure including the patterned intermediate part and the build material support structure temporarily bound together at the patterned etchable connection.

8. The method as defined in claim 7 wherein the build material support structure is a multi-layer structure, and wherein prior to patterning the other layer of metallic build material the method further comprises iteratively applying additional metallic build material layers and selectively applying the binding agent to the additional metallic build material layers to define several layers of the build material support structure and several layers of the region of the patterned intermediate part, wherein the several layers of the build material support structure and the several layers of the region of the patterned intermediate part are separated by additional non-patterned metallic build material.

9. The method as defined in claim 1 wherein patterning the metallic build material layers includes:
iteratively applying individual metallic build material layers;
selectively applying the binding agent to each of the individual metallic build material layers to define several layers of the build material support structure and several layers of the patterned intermediate part; and
selectively applying the i) the binding agent and the separate agent or ii) the combined agent on each of the individual build material layers to define the patterned etchable connection between the several layers of the build material support structure and the several layers of the patterned intermediate part.

10. The method as defined in claim 1 wherein the etch sensitizer is selected from the group consisting of soluble or dispersible ferrocyanides, soluble thiocyanates, a nitrate salt, thermally decomposable soluble organic substances, potassium chloride, and a combination thereof.

11. The method as defined in claim 10 wherein one of:
the soluble ferrocyanide is sodium hexacyanoferrate or potassium hexacyanoferrate;
the dispersible ferrocyanide is iron(II,III) hexacyanoferrate(II,III); or
the nitrate is potassium nitrate, sodium nitrate, magnesium nitrate, calcium nitrate, barium nitrate, or ammonium nitrate; or
the soluble thiocyanate is sodium thiocyanate or potassium thiocyanate.

12. A liquid functional agent for three-dimensional (3D) printing, comprising:
an etch sensitizer that is to:
i) decompose at a temperature within a de-binding temperature range, a sintering temperature range, or combinations thereof of an intermediate structure to generate a sensitized product within a portion of the intermediate structure that is patterned with the liquid functional agent, the decomposing etch sensitizer being selected from the group consisting of soluble or dispersible ferrocyanides, soluble thiocyanates, a nitrate salt, thermally decomposable soluble organic substances, and a combination thereof; or
ii) be non-reactive at the temperature within the de-binding temperature range, the sintering temperature range, or combinations thereof of the intermediate structure to remain within the portion of the intermediate structure that is patterned with the liquid functional agent, the non-reactive etch sensitizer being potassium chloride;
any of a surfactant or a dispersing aid; and
a balance of water.

13. The liquid functional agent as defined in claim 12 wherein one of:
the soluble ferrocyanide is sodium hexacyanoferrate or potassium hexacyanoferrate;
the dispersible ferrocyanide is iron(II,III) hexacyanoferrate(II,III); or
the nitrate is potassium nitrate, sodium nitrate, magnesium nitrate, calcium nitrate, barium nitrate, or ammonium nitrate; or
the soluble thiocyanate is sodium thiocyanate or potassium thiocyanate.

14. The liquid functional agent as defined in claim 12, further comprising a binder.

15. A three-dimensional (3D) printed article, comprising:
a first metallic object;
a second metallic object; and
an irreversibly etchable metal connection between the first and second metallic objects, wherein the irreversibly etchable metal connection comprises a sensitized product or an etch sensitizer that preferentially etches relative to the first and second metallic objects.
